(19) United States
(12) Patent Application Publication
(10) Pub. No.: US 2025/0169304 A1
(43) Pub. Date: May 22, 2025

(54) DISPLAY DEVICE

(71) Applicant: KunShan Go-Visionox Opto-Electronics Co., Ltd, Kunshan (CN)

(72) Inventors: Chuanzhi XU, Kunshan (CN); Lei YAO, Kunshan (CN); Manman LI, Kunshan (CN); Siming HU, Kunshan (CN)

(73) Assignee: KunShan Go-Visionox Opto-Electronics Co., Ltd, Kunshan (CN)

(21) Appl. No.: 18/938,689

(22) Filed: Nov. 6, 2024

(30) Foreign Application Priority Data
Nov. 17, 2023 (CN) 202311541530.2

(51) Int. Cl. H10K 59/131; H10K 59/80; H10K 102/00

(52) U.S. Cl. CPC H10K 59/131; H10K 59/8722; H10K 2102/351

(57) ABSTRACT

A display device includes a substrate, a first film layer group, a second film layer group, and a sealing part. A bezel region of the substrate includes a first partition, and the first partition includes at least part of a fan-out region. The first film layer group includes multiple first wires, and the multiple first wires are located at least in the fan-out region. The second film layer group includes at least one second wire. At least in the first partition, an orthographic projection of the at least one second wire on the substrate is located outside an overlapping region between an orthographic projection of the first film layer group on the substrate and an orthographic projection of the sealing part on the substrate.

### CROSS-REFERENCE TO RELATED APPLICATION(S)

This application claims priority to Chinese Patent Application No. 202311541530.2 filed Nov. 17, 2023, the disclosure of which is incorporated herein by reference in its entirety.

### TECHNICAL FIELD

The present disclosure relates to the field of display technologies, and in particular to, a display device.

### BACKGROUND

With the continuous development of display technologies, the application range of a display panel is becoming increasingly wider, and consumers and panel manufacturers have increasingly higher requirements for the display quality of the display panel. The display quality of existing display panels still needs to be further improved.

### SUMMARY

The present disclosure provides a display device to improve the display quality of the display device.

To achieve the above-described technical purposes, an embodiment of the present disclosure provides the following technical solutions.

A display device includes a substrate, a first film layer group, a second film layer group and a sealing part. The substrate includes a display region and a bezel region, the bezel region includes a first partition, and the first partition includes at least part of a fan-out region. The first film layer group is located on the substrate and includes multiple first wires, and the multiple first wires are located at least in the fan-out region. The second film layer group is located on the substrate and includes at least one second wire. The sealing part is located in the bezel region and on one side of the first film layer group facing away from the substrate, where at least in the first partition, an orthographic projection of the at least one second wire on the substrate is located outside an overlapping region between an orthographic projection of the first film layer group on the substrate and an orthographic projection of the sealing part on the substrate, or a region where an orthographic projection of the first film layer group on the substrate, an orthographic projection of the sealing part on the substrate, an orthographic projection of the at least one second wire on the substrate, and the first partition overlap simultaneously is a first region, and an area of the first region is less than 15% an area of an overlapping region between the orthographic projection of the sealing part on the substrate and the first partition, or the number of first wires whose orthographic projections on the substrate at least partially overlap with the first region is less than or equal to 4.

Optionally, the sealing part is located on one side of the second film layer group facing away from the substrate, and the sealing part covers at least part of the at least one second wire in at least the first partition.

Optionally, an overlapping region between the orthographic projection of the at least one second wire on the substrate and the first partition is located outside the overlapping region between the orthographic projection of the sealing part on the substrate and the first partition

Optionally, at least in the first partition, the at least one second wire is located on one side of the multiple first wires facing away from the display region.

Optionally, the bezel region further includes a second partition and/or a third partition, the second partition and the first partition are separately located on two adjacent sides of the display region, and/or the first partition and the third partition are separately located on two opposite sides of the display region; and in the second partition and/or the third partition, an orthographic projection of one of the first film layer group and the second film layer group on the substrate overlaps with the orthographic projection of the sealing part on the substrate, and an orthographic projection of the other of the first film layer group and the second film layer group on the substrate is located outside the orthographic projection of the sealing part on the substrate.

Optionally, the bezel region further includes a second partition and/or a third partition, the second partition and the first partition are separately located on two adjacent sides of the display region, and/or the first partition and the third partition are separately located on two opposite sides of the display region; the first film layer group further includes at least one third wire; in the second partition and/or the third partition, the sealing part covers at least part of the at least one third wire; optionally, the at least one second wire and at least one first wire among the multiple first wires extend from the first partition to the second partition; in the second partition, the at least one third wire is located on one side of the at least one second wire facing away from the multiple first wires; optionally, the at least one second wire extends from the first partition to the third partition via the second partition, and the at least one third wire extends from the second partition to the third partition; in the third partition, the at least one third wire is located on one side of the at least one second wire facing away from the display region; optionally, the at least one third wire is electrically connected to the at least one second wire; optionally, the at least one third wire and the multiple first wires are located on the same film layer; and optionally, the display device further includes a first insulating layer located between the first film layer group and the second film layer group; in the second partition and/or the third partition, the first insulating layer is located between the at least one third wire and the sealing part, and the first insulating layer is in contact with the sealing part.

Optionally, the bezel region further includes a second partition and/or a third partition, the second partition and the first partition are separately located on two adjacent sides of the display region, and/or the first partition and the third partition are separately located on two opposite sides of the display region; the at least one second wire extends from the first partition to the second partition, and/or the at least one second wire extends from the first partition to the third partition via the second partition; in the second partition and/or the third partition, the sealing part covers at least part of the at least one second wire; optionally, at least one first wire among the multiple first wires extends from the first partition to the second partition; and optionally, the at least one first wire extending to the second partition includes at least one of a start signal line, a clock signal line, a high potential direct current signal line, or a low potential direct current signal line.

Optionally, at least two first wires among the multiple first wires are located in different film layers, and optionally, two adjacent first wires among the multiple first wires are located in different film layers, and first wires on two sides among three adjacent first wires are located on the same film layer.

Optionally, a thickness of the at least one second wire is greater than a thickness of a first wire of the multiple first wires.

Optionally, the display device includes a first insulating layer located between the first film layer group and the second film layer group, where at least in the first partition, the first insulating layer is located between the multiple first wires and the sealing part, and the first insulating layer is in contact with the sealing part.

Optionally, at least in the first partition, an overlapping region between the orthographic projection of the sealing part on the substrate and an orthographic projection of the first insulating layer on the substrate overlaps with at least part of the orthographic projection of the at least one second wire on the substrate; or at least in the first partition, the first insulating layer includes a first opening, and an overlapping region between the orthographic projection of the sealing part on the substrate and an orthographic projection of the first opening on the substrate overlaps with at least part of the orthographic projection of the at least one second wire on the substrate; and/or the bezel region further includes a second partition and/or a third partition, the second partition and the first partition are separately located on two adjacent sides of the display region, and/or the first partition and the third partition are separately located on two opposite sides of the display region; in the second partition and/or the third partition, an overlapping region between the orthographic projection of the sealing part on the substrate and the orthographic projection of the first insulating layer on the substrate overlaps with at least part of the orthographic projection of the at least one second wire on the substrate; or in the second partition and/or the third partition, the first insulating layer includes a second opening; in the second partition and/or the third partition, an overlapping region between the orthographic projection of the sealing part on the substrate and an orthographic projection of the second opening on the substrate overlaps with at least part of the orthographic projection of the at least one second wire on the substrate.

Optionally, the sealing part is located on one side of the second film layer group facing away from the substrate, the second film layer group further includes at least one fourth wire located at least in the first partition, and the at least one fourth wire includes at least one first wire segment extending in a first direction; in the first partition, at least part of an orthographic projection of the at least one first wire segment on the substrate overlaps with the orthographic projection of the sealing part on the substrate, and the first direction is perpendicular to an edge of the display region facing the first partition; optionally, the at least one fourth wire and the at least one second wire are located on the same film layer; optionally, the at least one fourth wire further includes at least one second wire segment extending in a second direction and located in the first partition, the sealing part covers at least part of the at least one first wire segment, an orthographic projection of the at least one second wire segment on the substrate is located outside the orthographic projection of the sealing part on the substrate and is located on one side of the sealing part facing the display region, and the first direction intersects the second direction; optionally, the second direction is parallel to an edge of the display region facing the first partition; optionally, the at least one second wire is a first power line, and the at least one fourth wire is a second power line; optionally, the display device further includes at least one pixel circuit and at least one light-emitting element which are located in the display region of the substrate, the at least one pixel circuit is electrically connected to a first electrode of the at least one light-emitting element, the at least one second wire is electrically connected to a second electrode of the at least one light-emitting element, and the at least one fourth wire is electrically connected to the at least one pixel circuit; and optionally, the at least one fourth wire further includes at least one third wire segment extending in the second direction, a region where the orthographic projection of the first film layer group on the substrate, the orthographic projection of the sealing part on the substrate, an orthographic projection of the at least one third wire segment on the substrate, and the first partition overlap simultaneously is a second region, and in the first direction, a width of the second region is less than or equal to 15% of a width of the overlapping region between the orthographic projection of the sealing part on the substrate and the first partition; or an orthographic projection of the at least one third wire segment on the substrate is located outside the orthographic projection of the sealing part on the substrate, and the at least one third wire segment is located on one side of the sealing part facing the display region; and optionally, two first wire segments are provided, two second wire segment are provided, the third wire segment is located between the two second wire segments, one end of the third wire segment is electrically connected to one first wire segment of the two first wire segments and one second wire segment of the two second wire segments, and the other end of the third wire segment is electrically connected to the other first wire segment of the two first wire segments and the other second wire segment of the two second wire segments.

Optionally, the multiple first wires includes at least one of a start signal line, a clock signal line, a high potential direct current signal line, a low potential direct current signal line, or a signal connection line for transmitting a data signal; optionally, the display device further includes at least one pixel circuit and at least one light-emitting element which are located in the display region of the substrate, the at least one pixel circuit is electrically connected to a first electrode of the at least one light-emitting element, and the at least one second wire is electrically connected to a second electrode of the at least one light-emitting element; optionally, the display device further includes multiple data lines located in the display region of the substrate, at least part of the multiple first wires are electrically connected to respective ones of the multiple data lines and include a signal connection line for transmitting a data signal, the multiple data lines extend in a first direction, and the first partition and the display region are arranged in the first direction; optionally, the display device further includes at least one scanning circuit located in the bezel region of the substrate, at least part of the multiple first wires is electrically connected to the at least one scanning circuit and include at least one of a start signal line, a clock signal line, a high potential direct current signal line, or a low potential direct current signal line; optionally, at least in the display region, the second film layer group is located on the side of the first film layer group facing away from the substrate; optionally, the display device further includes a cover plate, and the cover plate is located on one side of the sealing part facing away from the substrate; optionally, the display device further includes a bonding region, the bonding region is located in the first partition and located on one side of the orthographic projection of the sealing part on the substrate facing away from the display region; and optionally, the sealing part includes glass frit.

Optionally, the first film layer group further includes a fifth wire located in the first partition and located between the multiple first wires and the at least one second wire, and the sealing part covers at least part of the fifth wire; and optionally, the fifth wire is disposed in a floating manner.

In the embodiments of the present disclosure, at least in the first partition, the orthographic projection of the at least one second wire on the substrate is located outside the overlapping region between the orthographic projection of the first film layer group on the substrate and the orthographic projection of the sealing part on the substrate; or the region where the orthographic projection of the first film layer group on the substrate, the orthographic projection of the sealing part on the substrate, the orthographic projection of the at least one second wire on the substrate, and the first partition overlap simultaneously is the first region, the area of the first region is less than 15% of the area of the overlapping region between the orthographic projection of the sealing part on the substrate and the first partition, or the number of first wires whose orthographic projections on the substrate at least partially overlap with the first region is less than or equal to 4. Therefore, in the first partition, an area over which the at least one second wire does not overlap or overlaps with the first film layer group below the sealing part is reduced, so that the height of the sealing part in the first partition is reduced, and thus the difference between the height of the sealing part in the first partition and the height of the sealing part in other bezels is reduced, thereby facilitating improvement of the phenomenon of Newton's rings. In addition, compared with the technical solution that the Newton's rings are improved by increasing the thickness of the sealing part, in the embodiments of the present disclosure, there is no need to increase the material of the sealing part, and thus the cost of the material is not increased. In conclusion, in the embodiments of the present disclosure, the problem of Newton's rings of the display device is alleviated on the basis of controlling the cost, thereby improving the display quality of the display device.

It is to be understood that the contents described in this section are not intended to identify key or critical features of the embodiments of the present disclosure, nor intended to limit the scope of the present disclosure. Other features of the present disclosure will be readily understood from the following description.

### BRIEF DESCRIPTION OF DRAWINGS

In order to describe technical solutions in embodiments of the present disclosure more clearly, the drawings used for describing the embodiments will be briefly introduced below. Apparently, the drawings in the following description are merely some embodiments of the present disclosure. For those of ordinary skill in the art, other drawings may also be obtained without creative labor according to these drawings.

FIG. 1 is a top view of a comparative example according to an embodiment of the present disclosure;

FIG. 2 is a cross-sectional view taken along A-A of FIG. 1;

FIG. 3 is a top view of a display device according to an embodiment of the present disclosure;

FIG. 4 is a cross-sectional view taken along C-C of FIG. 3;

FIG. 5 is a top view of another comparative example according to an embodiment of the present disclosure;

FIG. 6 is a cross-sectional view taken along E-E of FIG. 5;

FIG. 7 is a partial top view of a first partition of a display device according to an embodiment of the present disclosure;

FIG. 8 is a partial top view of a first partition of another display device according to an embodiment of the present disclosure;

FIG. 9 is a cross-sectional view taken along N-N of FIG. 8;

FIG. 10 is a top view of another display device according to an embodiment of the present disclosure;

FIG. 11 is a cross-sectional view taken along G-G of FIG. 10;

FIG. 12 is a top view of another display device according to an embodiment of the present disclosure;

FIG. 13 is a cross-sectional view taken along I-I of FIG. 12;

FIG. 14 is a top view of another display device according to an embodiment of the present disclosure;

FIG. 15 is a cross-sectional view taken along K-K of FIG. 14;

FIG. 16 is a top view of another display device according to an embodiment of the present disclosure;

FIG. 17 is a cross-sectional view taken along M-M of FIG. 16;

FIG. 18 is another cross-sectional view taken along G-G of FIG. 10;

FIG. 19 is another cross-sectional view taken along G-G of FIG. 10;

FIG. 20 is another cross-sectional view taken along K-K of FIG. 14;

FIG. 21 is another cross-sectional view taken along M-M of FIG. 16;

FIG. 22 is another cross-sectional view taken along M-M of FIG. 16;

FIG. 23 is another cross-sectional view taken along M-M of FIG. 16;

FIG. 24 is a partial top view of a first partition of another display device according to an embodiment of the present disclosure;

FIG. 25 is a partial top view of a first partition of another display device according to an embodiment of the present disclosure;

FIG. 26 is a partial top view of a first partition of another display device according to an embodiment of the present disclosure;

FIG. 27 is a partial top view of a first partition of another display device according to an embodiment of the present disclosure;

FIG. 28 is a partial top view of a first partition of another display device according to an embodiment of the present disclosure;

FIG. 29 is a cross-sectional view taken along 0-0 of FIG. 28;

FIG. 30 is a partial top view of a first partition of another display device according to an embodiment of the present disclosure;

FIG. 31 is another cross-sectional view taken along G-G of FIG. 10;

FIG. 32 is a top view of another display device according to an embodiment of the present disclosure; and

FIG. 33 is a cross-sectional view of a display region of a display device according to an embodiment of the present disclosure.

### DETAILED DESCRIPTION

In order that those skilled in the art will better understand the solutions of the present disclosure, the technical solutions adopted, and the technical effects to be achieved by the present disclosure, the technical solutions of embodiments of the present disclosure will be clearly and completely described below in conjunction with the accompanying drawings of the embodiments of the present disclosure. Apparently, the described embodiments are merely some embodiments of the present disclosure, rather than all of the embodiments. All other embodiments obtained by those of ordinary skill in the art based on the embodiments of the present disclosure without needing creative efforts shall all fall in the scope of protection of the present disclosure.

It is to be noted that the terms “first”, “second” and the like in the Description and claims of the present disclosure, and in the foregoing drawings, are used for distinguishing between similar objects and not necessarily for describing a particular order or sequential order. It is to be understood that the data so used are interchangeable as appropriate so that embodiments of the present disclosure described herein can be implemented in an order other than those illustrated or described herein. Moreover, the terms “include” and “have” as well as any variations thereof, are intended to cover a non-exclusive inclusion, for example, a process, a method, a system, a product, or a device that includes a series of steps or units is not necessarily limited to those steps or units expressly listed, but may include other steps or units not expressly listed or inherent to such process, method, product, or device.

In the related art, the edge of the display panel has the phenomenon of Newton's rings, which affects the display quality of the display panel. The inventor researches and finds that the reason of the problem is as follows.

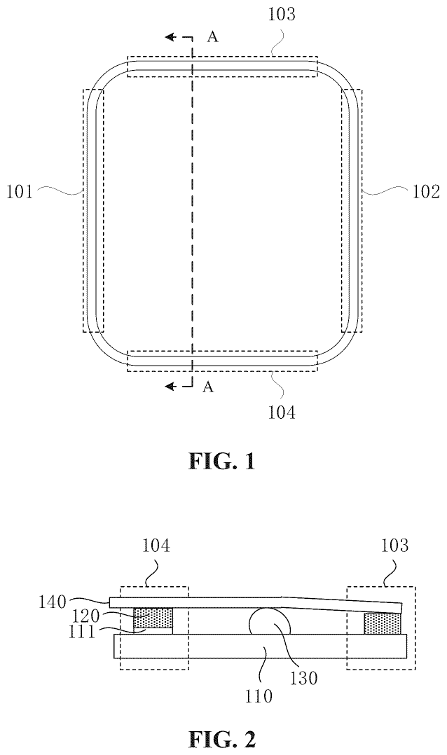

The phenomenon of Newton's rings is mostly found in OLED display panels, especially in OLED display panels encapsulated by using glass frit (commonly referred to as frit encapsulation). FIG. 1 is a top view of a comparative example according to an embodiment of the present disclosure. Referring to FIG. 1, the display device includes a left bezel 101, a right bezel 102, an upper bezel 103 and a lower bezel 104. In some embodiments, a drive chip is generally disposed on the lower bezel 104. Therefore, the lower bezel 104 is disposed in a different wiring manner from other bezels (including the left bezel 101, the right bezel 102, and the upper bezel 103), and the left bezel 101, the right bezel 102 and the upper bezel 103 are disposed in substantially the same wiring manner.

FIG. 2 is a cross-sectional view taken along A-A of FIG. 1. Referring to FIG. 2, the display device includes an array substrate 110, a sealing part 120 and a cover plate 140 which are disposed in a stacked manner, and a spacer 130 is disposed between the array substrate 110 and the cover plate. A thickness of a metal wire layer in the array substrate 110 located at the lower bezel 104 is greater than a thickness of a metal wire layer in the array substrate 110 located at the upper bezel 103, and/or the number of stacked film layers of a metal wire layer in the array substrate 110 located at the lower bezel 104 is greater than the number of stacked film layers of a metal wire layer in the array substrate 110 located at the upper bezel 103. In an embodiment, the array substrate 110 located at the lower bezel 104 has a thickness of one more metal wire layer 111 than the array substrate 110 located at the left bezel 101, the right bezel 102 and the upper bezel 103. A thickness of the sealing part 120 and a thickness of the spacer 130 may be considered to be uniform. Therefore, the cover plate 140 has a certain inclination angle, and the phenomenon of Newton's rings appears on the display device. Further, the inventors have also found that the stacked area of the metal wire layer having a relatively large number of stacked layers and located at the lower bezel 104 has a certain impact on the phenomenon of Newton's rings.

In an embodiment, the impact of differences between the lower bezel 104 and other bezels (including the left bezel 101, the right bezel 102 and the upper bezel 103) may be reduced in a manner of thickening the height of the sealing part 120 as a whole. In some embodiments, due to the difference in wiring, a height of the lower bezel 104 is 0.6 um higher than a height of another bezel. If the thickness of the sealing part 120 is 3 um, then a ratio of the difference in height is 0.6/(3+0.6)≈0.17. If the thickness of the sealing part 120 is 5 um, then a ratio of the difference in height is 0.6/(5+0.6)≈0.11. However, more encapsulation materials are required and thus the cost is relatively high in this technical solution.

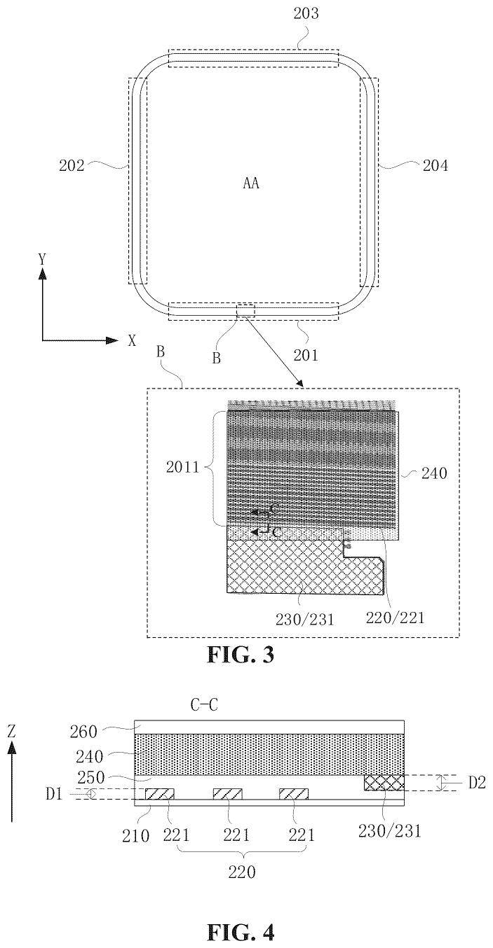

In view of this, embodiments of the present disclosure provide a display device. FIG. 3 is a top view of a display device according to an embodiment of the present disclosure, and FIG. 4 is a cross-sectional view taken along C-C of FIG. 3. FIG. 3 further shows an enlarged structure of a region B. Referring to FIG. 3 and FIG. 4, the display device includes a substrate 210, a first film layer group 220, a second film layer group 230 and a sealing part 240. The substrate 210 includes a display region AA and a bezel region. The bezel region includes a first partition 201, and the first partition 201 includes at least part of a fan-out region 2011. The first film layer group 220 is located on the substrate 210. The first film layer group 220 includes multiple first wires 221, and the multiple first wires 221 are located at least in the fan-out region 2011. The second film layer group 230 is located on the substrate 210. The second film layer group 230 includes a second wire 231. The sealing part 240 is located in the bezel region and is located on one side of the first film layer group 220 facing away from the substrate 210. At least in the first partition 201, an orthographic projection of the second wire 231 on the substrate 210 is located outside an overlapping region between an orthographic projection of the first film layer group 220 on the substrate 210 and an orthographic projection of the sealing part 240 on the substrate 210. The sealing part 240 may be a bezel sealing part, such as a bezel sealing adhesive.

According to different shapes of the display region AA, shapes of the bezel region are also different. For example, the display region AA has a rectangle shape or a rounded rectangle shape, and the bezel region has a ring-shaped shape surrounding a rectangle or a rounded rectangle. For another example, the display region AA has a circular shape, and the bezel region has a ring-shaped shape surrounding a circle. No matter what the shape of the bezel region, the first partition 201 is disposed in the bezel region. In FIG. 3, for example, the first partition 201 is the lower bezel. The first partition 201 is used as a connection region between the display region and the drive chip and is usually provided with a large number of signals wires including the first wires 221, the at least one second wire 231, and the like. Multiple first wires 221 are provided, and the multiple first wires 221 are densely disposed in the fan-out region 2011 according to the certain rule. The bezel region may be located in the non-display region.

At least in the first partition 201, the orthographic projection of the second wire 231 on the substrate 210 is located outside an overlapping region between the orthographic projection of the first film layer group 220 on the substrate 210 and the orthographic projection of the sealing part 240 on the substrate 210. Specifically, at least in the first partition 201, the overlapping region between the orthographic projection of the first film layer group 220 on the substrate 210 and the orthographic projection of the sealing part 240 on the substrate 210 does not overlap with the orthographic projection of the second wire 231 on the substrate 210.

In this embodiment, at least in the first partition, the orthographic projection of the second wire on the substrate is located outside the overlapping region between the orthographic projection of the first film layer group on the substrate and the orthographic projection of the sealing part on the substrate. With this arrangement, a problem of a relatively large thickness caused by overlapping of the second wire 231 and the first wire 221 is avoided. Therefore, in the first partition, the second wire does not overlap with the first film layer group below the sealing part, so that the height of the sealing part in the first partition is reduced, and thus the difference between the height of the sealing part in the first partition and the height of the sealing part in other bezels is reduced, thereby facilitating improvement of the phenomenon of Newton's rings.

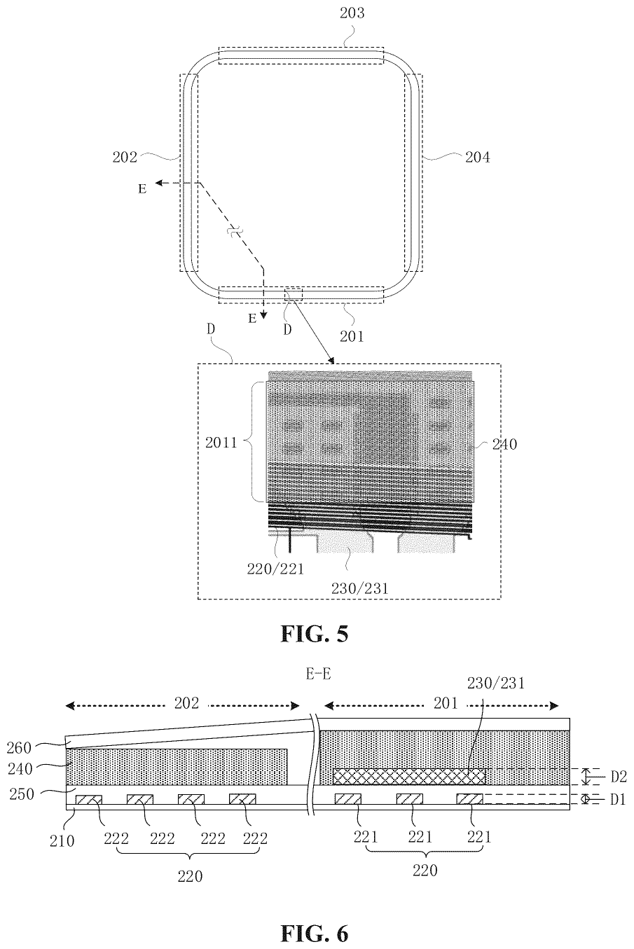

To better illustrate the beneficial effects achieved by the present disclosure, FIG. 5 is a top view of another comparative example according to an embodiment of the present disclosure, and FIG. 6 is a cross-sectional view taken along E-E of FIG. 5. FIG. 5 further shows an enlarged structure of a region D. Referring to FIG. 5 and FIG. 6, the orthographic projection of the second wire 231 on the substrate 210 is located in a region within the overlapping region between the orthographic projection of the first film layer group 220 on the substrate 210 and the orthographic projection of the sealing part 240 on the substrate 210, that is, the first wire 221 overlaps with the second wire 231.

It can be seen that, compared with the comparative examples in FIGS. 5 and 6, in the embodiments of the present disclosure, at least in the first partition, the orthographic projection of the second wire on the substrate is located outside the overlapping region between the orthographic projection of the first film layer group on the substrate and the orthographic projection of the sealing part on the substrate. Therefore, in the first partition, the second wire 231 does not overlap with the first film layer group below the sealing part 240, so that the height of the sealing part in the first partition is reduced, whereby the difference between the height of the sealing part in the first partition and the height of the sealing part in other bezels is reduced, and thus a difference between a height of the cover plate in the first partition and a height of the cover plate in other bezels is reduced, thereby facilitating improvement of the phenomenon of Newton's rings. In addition, compared with the technical solution that the Newton's rings are improved by increasing the thickness of the sealing part, in the embodiments of the present disclosure, there is no need to increase the material of the sealing part 230, and thus the cost of the material is not increased. In conclusion, in the embodiments of the present disclosure, the problem of Newton's rings of the display device is alleviated on the basis of controlling the cost, thereby improving the display quality of the display device.

With continued reference to FIG. 3 and FIG. 4, on the basis of the above-described embodiments, optionally, at least in the first partition 201, the at least one second wire 231 is located on one side of the multiple first wires 221 facing away from the display region AA. At least in the first partition 201, the at least one second wire 231 is located on one side of the overlapping region between the orthographic projection of the first film layer group 220 on the substrate and the orthographic projection of the sealing part on the substrate facing away from the display region AA. Compared with the comparative examples in FIG. 5 and FIG. 6, in the embodiments of the present disclosure, for the display region AA, it is equivalent that the second wire 231 with a higher height and/or a larger thickness is moved outwards. Therefore, the second wire 231 with a higher height and/or a larger thickness is further away from the display region AA. The reason for the Newton's rings is that the height of the cover plate is gradually changed, and if the height is fixed, the farther a distance from the start point of the gradual change to the display region AA is, the less impact on the display region AA is. It can be seen that in the embodiments of the present disclosure, the problem of Newton's rings is further alleviated, and thus the display effect of the display device is improved. In a thickness direction Z of the substrate 210, a thickness D2 of the second wire 231 may be greater than a thickness D1 of the first wire 221.

With continued reference to FIG. 3 and FIG. 4, on the basis of the above-described embodiments, optionally, the display device further includes a first insulating layer 250 located between the first film layer group 220 and the second film layer group 230. At least in the first partition 201, the first insulating layer 250 is located between the first wire 221 and the sealing part 240. Optionally, the first insulating layer 250 is in contact with the sealing part 240. Compared with the comparative examples shown in FIG. 5 and FIG. 6, in the first partition 201, the second wire 231 is disposed to move outwards, so that a contact area between the sealing part 240 and the second wire 231 is reduced, and the sealing part 230 may more contact the first insulating layer 250 below the second wire 231. The first insulating layer 250 may be an inorganic insulating layer. In some embodiments, a material of the sealing part 240 includes glass frit, a material of the first insulating layer 250 includes an inorganic insulating material such as silicon oxide and/or silicon nitride, and a material of the second wire 231 includes a metal material such as titanium aluminum titanium. A sealing effect that the sealing part 240 is in direct contact with the first insulating layer 250 is good, and a sealing effect that the sealing part 240 is in direct contact with the second wire 231 is poor. Therefore, the sealing part 230 can contact the first insulating layer 250 more in the embodiments of the present disclosure, thereby enhancing the sealing effect of the sealing part 240.

In conclusion, in the embodiments of the present disclosure, at least in the first partition 201, the orthographic projection of the second wire 231 on the substrate 210 is located outside the overlapping region between the orthographic projection of the first film layer group 220 on the substrate 210 and the orthographic projection of the sealing part 240 on the substrate 210. Further, the second wire 231 is disposed to be located on one side of the multiple first wires 221 facing away from the display region AA. In this way, at least following beneficial effects can be achieved.

In a first aspect, a height of the second wire 231 in the first partition 201 is reduced, that is, the difference between the height of the cover plate 260 in the first partition 210 and the height of the cover plate 260 in other bezels (including the second partition 202, the third partition 203, and the fourth partition 204) is reduced, thereby facilitating improvement of the phenomenon of Newton's rings.

In a second aspect, the farther a distance between the at least one second wire 231 with a relatively high height and the display region AA is, so that the farther a distance from a start point at which the height of the cover plate gradually changes to the display region AA is, and the less impact of Newton's rings on the display region AA is.

In a third aspect, in the first partition 201, the second wire 231 is moved outward, in a case where a position of the sealing part 240 remains unchanged, a contact area between the sealing part 240 and the second wire 231 is reduced, and at this time, the sealing part 240 is in more contact with the first insulating layer 250, thereby enhancing the sealing effect.

In a fourth aspect, in the embodiments of the present disclosure, there is no need to increase the material of the sealing part 240 in the embodiments of the present disclosure, and thus the cost of the material is not increased. Compared with a manner of adjusting the height difference by increasing the thickness of the sealing part 240 in other partitions (including the second partition 202, the third partition 203, and the fourth partition 204), or a manner of adjusting the height difference by adding a thickness compensation layer in other partitions (the increase in the thickness of the bezel region may cause an increase in materials of the spacer (SPC) and a pixel definition layer (PDL) in the display region), in this embodiment, the material of the spacer (SPC) and the pixel definition layer (PDL) in the display region may be reduced, thereby reducing the cost.

On the basis of the above-described embodiments, multiple manners for setting the relative position of the sealing part 240 and the second film layer group 230 are provided. Several manners among the multiple manners are described below, but are not intended to limit the present disclosure.

Optionally, in the first partition 201, the number of film layers in which wires covered by the sealing part 240 are located is greater than or equal to the number of film layers in which wires covered by the sealing part 240 are located in other partitions (including at least one of the second partition 202, the third partition 203, or the fourth partition 204).

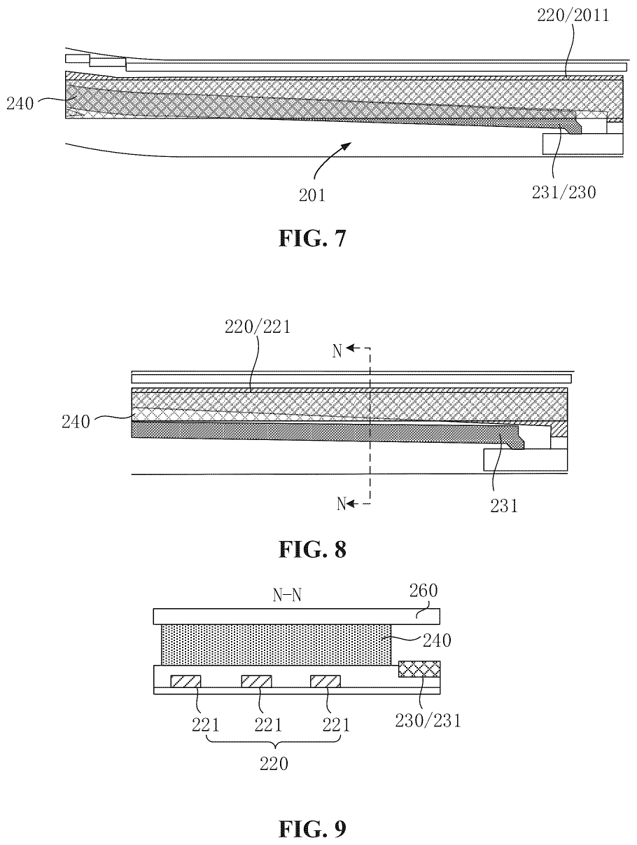

FIG. 7 is a partial top view of a first partition of a display device according to an embodiment of the present disclosure. Referring to FIG. 7 and FIG. 4, in an embodiment of the present disclosure, optionally, the sealing part 240 is located on one side of the second film layer group 230 facing away from the substrate 210, and at least in the first partition 201, the sealing part 240 covers at least part of the second wire 231. At least in the first partition 201, the orthographic projection of the sealing part 240 on the substrate 210 at least partially overlap with the orthographic projection of the second wire 231 on the substrate 210. At least in the first partition 201, in a region covered by the sealing part 240, the orthographic projection of the second wire 231 on the substrate 210 may not overlap with the orthographic projection of the first wire 221 on the substrate 210. At least in the first partition 201, in a region covered by the sealing part 240, the second wire 231 and the first wires 221 are arranged in a staggered manner. With this arrangement, it is conducive to making a width of the sealing part 240 located in the first partition 201 wider, to enhance the encapsulation effect of the sealing part 240, and/or it is conducive to reducing a width of a bezel corresponding to the first partition 201. In addition, it may be learned from the foregoing analysis that the embodiment shown in FIG. 7 can achieve at least beneficial effects in at least four aspects, and the details are not repeated here.

FIG. 8 is a partial top view of a first partition of another display device according to an embodiment of the present disclosure, and FIG. 9 is a cross-sectional view taken along N-N of FIG. 8. Referring to FIG. 8 and FIG. 9, in an embodiment of the present disclosure, optionally, the overlapping region between the orthographic projection of the second wire 231 on the substrate 210 and the first partition 201 is located outside the overlapping region between the orthographic projection of the sealing part 240 on the substrate 210 and the first partition 201. That is, in the first partition 201, the second wire 231 and the sealing part 240 are disposed in a staggered manner. The overlapping region between the orthographic projection of the sealing part 240 on the substrate 210 and the first partition 201 may not overlap with the orthographic projection of the second wire 231 on the substrate 210. In the embodiments of the present disclosure, the impact of the second wire 231 with a relatively large thickness on the height difference of the cover plate can be reduced, thereby facilitating improvement of the phenomenon of Newton's rings. In a thickness direction Z of the substrate 210, the thickness D2 of the second wire 231 may be greater than the thickness D1 of the first wire 221.

It can be seen from the embodiment shown in FIG. 8 and FIG. 9 that the sealing part 240 overlaps with the first film layer group 220. It may be learned from the foregoing analysis that a thickness of the first film layer group 220 is less than a thickness of the second wire 231. Therefore, the sealing part 240 is disposed to overlap with the first film layer group 220, and the sealing part 240 does not overlap with the second wire 231, thereby facilitating reducing the height of the sealing part 240 located in the first partition 201. In some embodiments, with this arrangement, a setting manner of the sealing part 240 in the first partition 201 is the same as a setting manner of the sealing part 240 in other partitions, thereby further making the height of the cover plate located on the sealing part 240 consistent and improving the display quality of the display device.

In the above-described embodiments, a setting manner of each film layer in the first partition 201 of the display device is limited. The setting manner of each film layer of the display device is further described below with reference to other partitions of the display device.

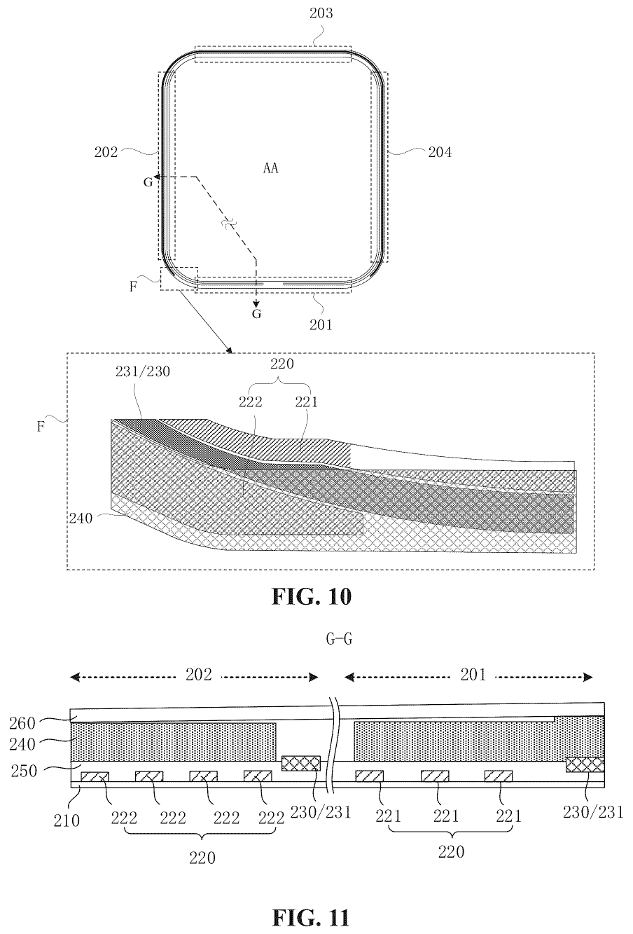

FIG. 10 is a top view of another display device according to an embodiment of the present disclosure, and FIG. 11 is a cross-sectional view taken along G-G of FIG. 10. FIG. 10 further shows an enlarged structure of a region F. A region F is a transition region between the first partition 201 and the second partition 202. The region F may also be considered as a part of the first partition 201, the region F may also be considered as a part of the second partition 202, and the region F may also be considered as a part of the first partition 201 plus a part of the second partition 202.

Referring to FIG. 10 and FIG. 11, on the basis of the above-described embodiments, optionally, the bezel region further includes a second partition 202 and/or a third partition 203. The second partition 202 and the first partition 201 are located on two adjacent sides of the display region AA. Optionally, the second partition 202 is contiguous with the first partition 201. The first partition 201 and the third partition 203 are located on two opposite sides of the display region AA. Optionally, the bezel region further includes a fourth partition 204. The second partition 202 and the fourth partition 204 are located on two opposite sides of the display region AA. Optionally, the second partition 202 and the fourth partition 204 are symmetrically disposed. Alternatively, the bezel region includes two second partitions (the partition 202 and the partition 204, respectively), and the two second partitions are located on two opposite sides of the display region AA.

Optionally, the bezel region further includes a second partition 202 and a third partition 203. In other embodiments, according to the shape of the display region AA, the setting manner of the bezel, and the like, the display device may further include only the first partition 201 and the second partition 202, or may further include only the first partition 201, the third partition 203 and the like, which are set as required in practical applications.

Optionally, in the second partition 202 and/or the third partition 203, an orthographic projection of one of the first film layer group 220 or the second film layer group 230 on the substrate 210 overlaps with the orthographic projection of the sealing part 240 on the substrate, and an orthographic projection of the other of the first film layer group 220 or the second film layer group 230 on the substrate 210 is located outside the orthographic projection of the sealing part 240 on the substrate 210.

Optionally, in the second partition 202 and/or the third partition 203, the orthographic projection of the first film layer group 220 on the substrate 210 overlaps with the orthographic projection of the sealing part 240 on the substrate, and the orthographic projection of the second film layer group 230 on the substrate 210 is located outside the orthographic projection of the sealing part 240 on the substrate 210.

Optionally, in the second partition 202 and/or the third partition 203, the orthographic projection of the second film layer group 230 on the substrate 210 overlaps with the orthographic projection of the sealing part 240 on the substrate, and the orthographic projection of the first film layer group 220 on the substrate 210 is located outside the orthographic projection of the sealing part 240 on the substrate 210.

Referring to FIG. 10 and FIG. 11, in an embodiment of the present disclosure, optionally, the first film layer group 220 further includes at least one third wire 222 located in the second partition 202 and/or the third partition 203. In the second partition 202 and/or the third partition 203, the sealing part 240 covers at least part of the at least one third wire 222, that is, the sealing part 240 covers at least part of the first film layer group 220. In some embodiments, in the second partition 202 and the third partition 203, the sealing part 240 completely covers the third wire 222. Optionally, in the second partition 202, the orthographic projection of the sealing part 240 on the substrate 210 is located outside the orthographic projection of the second film layer group 230 on the substrate 210, which is equivalent to that in the second partition 202, the orthographic projection of the sealing part 240 on the substrate 210 does not overlap with the orthographic projection of the second film layer group 230 on the substrate 210. Optionally, in the third partition 203, the orthographic projection of the sealing part 240 on the substrate 210 is located outside the orthographic projection of the second film layer group 230 on the substrate 210, which is equivalent to that in the third partition 203, the orthographic projection of the sealing part 240 on the substrate 210 does not overlap with the orthographic projection of the second film layer group 230 on the substrate 210. Optionally, the number of third wires 222 may be one, two, or more. Different wires located in the same film layer may be obtained by performing the patterning processing on this film layer, thereby simplifying the process.

It may be learned from the foregoing analysis that in the first partition 201, the sealing part 240 covers the first film layer group 220, or the sealing part 240 covers the first film layer group 220 and the at least one second wire 231. Two conditions are described below, separately.

Referring to FIG. 10 and FIG. 11, in an embodiment, in the first partition 201, the sealing part 240 covers the first wire 221 and at least part of the second wire 231. In the second partition 202 and/or the third partition 203, the sealing part 240 covers the third wire 222. Since both the first wire 221 and the third wire 222 belong to the first film layer group 220, a height of the first wire 221 and a height of the third wire 222 are relatively consistent. It can be learned from the foregoing analysis that, compared with the comparative examples in FIG. 5 and FIG. 6, in the embodiments of the present disclosure, a height difference of the sealing part 240 located in different partitions (such as, the first partition 201 and the second partition 202) is reduced, thereby improving the display effect of the display device.

It is to be noted that FIG. 11 exemplarily shows a film layer relationship between the first partition 201 and the second partition 202 in a cross-sectional structure. Those skilled in the art may understand that the film layer relationship may also represent a film layer relationship between the first partition 201 and the third partition 203 in a cross-sectional structure, and represent a film layer relationship between the first partition 201 and the fourth partition 204 in a cross-sectional structure.

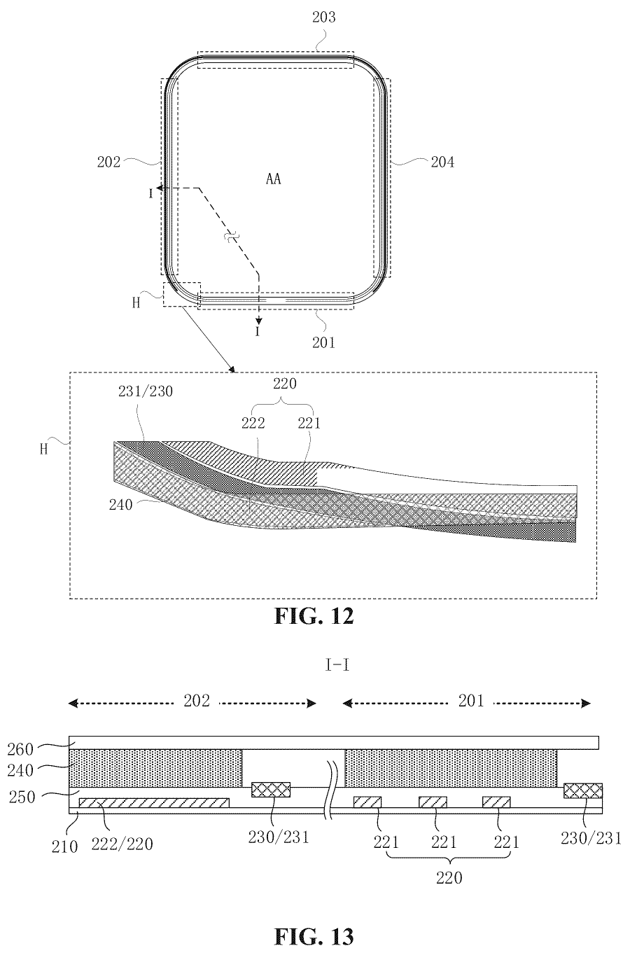

FIG. 12 is a top view of another display device according to an embodiment of the present disclosure, and FIG. 13 is a cross-sectional view taken along I-I of FIG. 12. FIG. 12 further shows an enlarged structure of a region H. Referring to FIG. 12 and FIG. 13, in another embodiment, in the first partition 201, the sealing part 240 and the second wire 231 are disposed in a staggered manner, that is, the sealing part 240 covers only the first wire 221. In the second partition 202 and/or the third partition 203, the sealing part 240 covers the third wire 222. Since both the first wire 221 and the third wire 222 belong to the first film layer group 220, a height of the first wire 221 and a height of the third wire 222 are relatively consistent. It can be seen that in the embodiments of the present disclosure, with this arrangement, setting manners of the film layers below the sealing parts 240 in the first partition 201 and other partitions (including the second partition 202, the third partition 203 and/or the fourth partition 204) are relatively consistent, so that the height difference of the sealing parts 240 in different bezel regions is reduced, and the display effect of the display device is improved.

It is to be noted that, it may be learned from FIG. 12 that, in the transition region domain H, a part that the sealing part 220 overlaps with the second wire 231 exists. Since an area of this part is relatively small, the impact on the overall height of the sealing part 220 may be ignored. In another aspect, since the height of the second wire 231 is set to be reduced in the embodiments of the present disclosure, the display effect can still be improved in this embodiment.

Optionally, referring to FIG. 10 to FIG. 13, in the second partition 202 and/or the third partition 203, the first insulating layer 250 is located between the at least one third wire 222 and the sealing part 240. Optionally, the first insulating layer 250 is in contact with the sealing part 240.

With continued reference to FIG. 10 to FIG. 13, in an embodiment of the present disclosure, optionally, the at least one second wire 231 and at least one first wire 221 extend from the first partition 201 to the second partition 202. With this arrangement, a signal of the drive chip may be transmitted to the second partition 202 through the first wire 221 and the second wire 231, and may further be transmitted to the third partition 203. In the second partition 202, the third wire 222 is located on one side of the second wire 231 facing away from the first wire 221. That is, the third wire 222 is located at the outermost side in the second partition 202, and the third wire 222 and the second wire 231 are disposed in a staggered manner. With this arrangement, it is conducive to disposing the sealing part 240 on the third wire 222 and being in contact with the first insulating layer 250 on the third wire 222, thereby enhancing the encapsulation effect of the sealing part 240. It can be learned from the foregoing analysis that in the first partition 201, the sealing part 240 is mainly in contact with the first insulating layer 250. Therefore, if a width of a portion located in the first partition 201 and on the sealing part 240 is set to be equal to a width of a portion located in other partitions 201 and on the sealing part 240, then the sealing effect of the sealing part 240 at each position can be made to be similar. In the embodiments of the present disclosure, there is no need to widen the width of the sealing part 240 due to the poor sealing effect in the first partition 201 (or other partitions). Therefore, in the embodiments of the present disclosure, it is conducive to reducing the amount of use of the material of the sealing part 240, thereby reducing the cost.

It is to be noted that FIG. 13 exemplarily shows a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

In some embodiments, the at least one second wire 231 and/or at least one first wire 221 extend from the first partition 201 to the second partition 202. The first wire 221 stops after the first wire 221 extends to the second partition 202, and does not extend to the third partition 203.

In some other embodiments, the at least one second wire 231 and the at least one first wire 221 extend from the first partition 201 to the second partition 202 and then to the third partition 203, and the at least one third wire 222 extends from the second partition 202 to the third partition 203. In the second partition 202, the at least one third wire 222 is located on one side of the at least one second wire 231 facing away from the first wire 221.

In some other embodiments, the at least one second wire 231 extends from the first partition 201 to the third partition 203 via the second partition 202. The at least one third wire 222 extends from the second partition 202 to the third partition 203. In the third partition 203, the at least one third wire 222 is located on one side of the at least one second wire 231 facing away from the display region AA.

On the basis of the above-described embodiments, optionally, the third wire 222 is electrically connected to the second wire 231. That is, the same signal may be transmitted simultaneously through the second wire 231 and the third wire 222. With this arrangement, it is conducive to reducing the signal transmission impedance.

On the basis of the above-described embodiments, optionally, the at least one third wire 222 and the first wire 221 are located in the same film layer, such as the same film layer. In some embodiments, the first film layer group 220 includes the first conductive layer and the second conductive layer, and both the first wire 221 and the at least one third wire 222 are located in the first conductive layer, or both the first wire 221 and the at least one third wire 222 are located in the second conductive layer.

In other embodiments, it may also be disposed in a manner that the first wire 221 is located in the first conductive layer, and the at least one third wire 222 is located in the second conductive layer; alternatively, the first wire 221 is located in the second conductive layer, and the at least one third wire 222 is located in the first conductive layer; or a part of first wires 221 are located in the first conductive layer, and another part of first wires 221 are located in the second conductive layer; alternatively, one part of third wires 222 are located in the first conductive layer, and another part of third wires 222 are located in the second conductive layer. Optionally, the third wire 222 and part of the second wire 231 are located in the same film layer, and the third wire 222 and part of the second wire 231 are located in different film layers. Optionally, the second wire 231 and part of the third wire 222 are located in the same film layer, and the second wire 231 and part of the third wire 222 are located in different film layers.

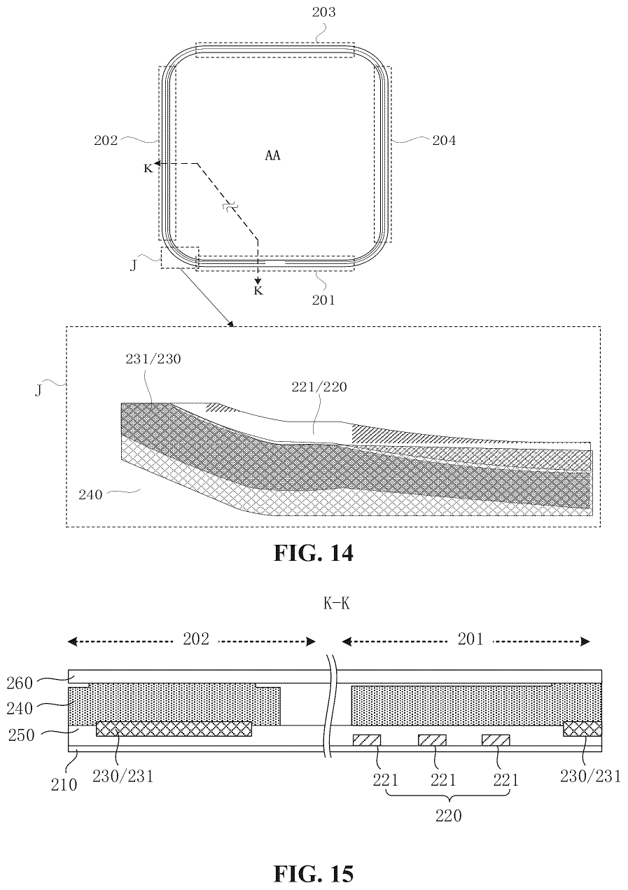

FIG. 14 is a top view of another display device according to an embodiment of the present disclosure, and FIG. 15 is a cross-sectional view taken along K-K of FIG. 14. FIG. 14 further shows an enlarged structure of a region J. Unlike the previous embodiments, the film layer covered by the sealing part 240 is changed in the bezel region other than the first partition 201.

Referring to FIG. 14 and FIG. 15, it is to be noted that FIG. 15 exemplarily shows a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

In another embodiment of the present disclosure, optionally, in the second partition 202 and/or the third partition 203, the sealing part 240 covers at least part of the second wire 231, which is equivalent to that the sealing part 240 covers at least part of the second film layer group 230. In the second partition 202 and/or the third partition 203, the sealing part 240 is located on one side of the second film layer group 230 facing away from the substrate 210. In some embodiments, in the second partition 202 and the third partition 203, the sealing part 240 completely covers the second wire 231. Optionally, in the second partition 202, the orthographic projection of the sealing part 240 on the substrate 210 is located outside the orthographic projection of the first film layer group 220 on the substrate 210, which is equivalent to that in the second partition 202, the orthographic projection of the sealing part 240 on the substrate 210 does not overlap with the orthographic projection of the first film layer group 220 on the substrate 210. Optionally, in the third partition 203, the orthographic projection of the sealing part 240 on the substrate 210 is located outside the orthographic projection of the first film layer group 220 on the substrate 210, which is equivalent to that in the third partition 203, the orthographic projection of the sealing part 240 on the substrate 210 does not overlap with the orthographic projection of the first film layer group 220 on the substrate 210.

It may be learned from the foregoing analysis that in the first partition 201, the sealing part 240 covers the first film layer group 220, or the sealing part 240 covers the first film layer group 220 and the second wire 231. Two conditions are described below, separately.

With continued reference to FIG. 14 and FIG. 15, in an embodiment, in the first partition 201, the sealing part 240 covers the first wire 221 and at least part of the second wire 231. In the second partition 202 and the third partition 203, the sealing part 240 covers the second wire 231. Since a height of the second wire 231 located in the first partition 201 and a height of the second wire 231 located in the second partition 202 are relatively consistent, a height of the sealing part 240 provided by the embodiments of the present disclosure in the first partition 201 and a height of the sealing part 240 in the second partition 202 are relatively consistent, thereby improving the display effect of the display device.

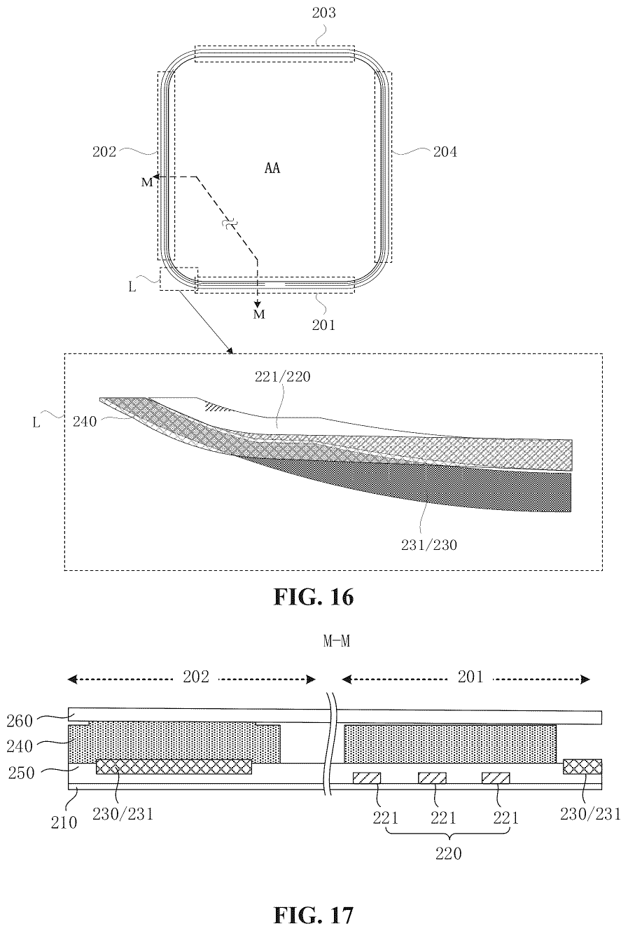

FIG. 16 is a top view of another display device according to an embodiment of the present disclosure, and FIG. 17 is a cross-sectional view taken along M-M of FIG. 16. FIG. 16 further shows an enlarged structure of a region L. Referring to FIG. 16 and FIG. 17, in another embodiment, in the first partition 201, the sealing part 240 and the at least one second wire 231 are disposed in a staggered manner, that is, the sealing part 240 covers only the first wire 221. In the second partition 202 and the third partition 203, the sealing part 240 covers the second wire 231.

It is to be noted that FIG. 17 exemplarily shows a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

Referring to FIG. 14 to FIG. 17, on the basis of the above-described embodiments, optionally, at least one first wire 221 extends from the first partition 201 to the second partition 202. With this arrangement, a signal of the drive chip may be transmitted to the second partition 202 through the first wire 221, and may further be transmitted to the third partition 203.

Optionally, the first wire 221 extending to the second partition 202 includes at least one of a start signal line sin, a clock signal line clk, a high potential direct current signal line VGH, or a low potential direct current signal line VGL. At least one scanning circuit is disposed in the second partition 202, and the at least one scanning circuit is configured to provide a scanning signal and/or a light emission control signal to the display region AA. A start signal is transmitted on a start signal line, and the start signal is used for controlling a start time at which the scanning circuit starts to perform a shift and then outputs. A clock signal is transmitted on the clock signal line, and the clock signal is used for controlling the frequency output by the shift of the scanning signal and/or controlling the pulse width of the scanning signal. The high potential direct current signal line and the low potential direct current signal line transmit a high potential direct current signal and a low potential direct current signal, respectively. The high potential direct current signal and the low potential direct current signal are used for providing a high direct current reference voltage and a low direct current reference voltage to the scanning circuit, respectively.

With continued reference to FIG. 14 to FIG. 17, on the basis of the above-described embodiments, optionally, at least one second wire 231 extends from the first partition 201 to the third partition 203 via the second partition 202. With this arrangement, a signal of the drive chip may be transmitted to the second partition 202 and the third partition 203 through the at least one second wire 231.

It is to be noted that FIG. 17 exemplarily shows a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

It is to be noted that, in the above-described embodiments, an example in which a setting manner of the sealing part 240 in the second partition 202 is the same as a setting manner of the sealing part 240 in the third partition 203 is used for exemplary description, which is not a limitation on the present disclosure. In other embodiments, a setting manner of the sealing part 240 in the second partition may be disposed to be different form a setting manner of the sealing part 240 in the third partition 203. For example, in the second partition 202, the sealing part 240 covers part or all of the at least one third wire 222. In the third partition 203, the sealing part 240 covers part or all of other wires, which may be set as required in practical application.

The first film layer group 220 may include one conductive layer or at least two conductive layers. The second film layer group 230 may include one conductive layer or at least two conductive layers. In the above-described embodiments, an example in which at least two first wires 221 are located in the same film layer and the first film layer group 220 may include one conductive layer is used for exemplary description, which is not a limitation on the present disclosure. Other embodiments will be described below.

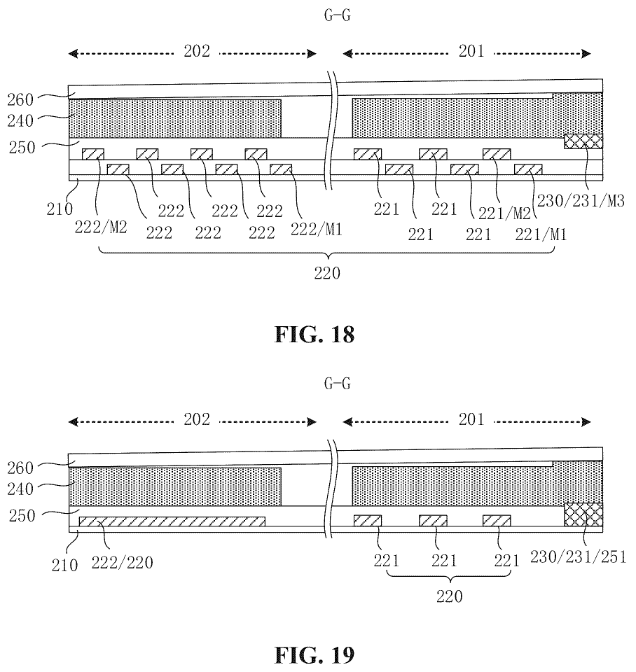

FIG. 18 is another cross-sectional view taken along G-G of FIG. 10. Referring to FIG. 18, in an embodiment of the present disclosure, optionally, at least two first wires 221 are located in different film layers. With this arrangement, it is conducive to disposing more wires within the same bezel width; on the other hand, if the number of signal lines are equal, then it is conducive to reducing the width of the bezel by means of this arrangement provided in the embodiments of the present disclosure. The first film layer group 220 may include a first conductive layer M1 and a second conductive layer M2. Optionally, one first wire of two adjacent first wires 221 is located in the first conductive layer M1, and the other first wire of the two adjacent first wires 221 is located in the second conductive layer M2. Optionally, the first conductive layer M1 may be a gate layer. For example, the first conductive layer M1 may be further configured to form a gate of a transistor in the at least one pixel circuit. Optionally, the second conductive layer M2 may be a capacitor plate layer, for example, the second conductive layer M2 may be further configured to form a second plate of a storage capacitor in the at least one pixel circuit, and a first plate of the storage capacitor may be located in the first conductive layer M1. The first conductive layer M1 and the second conductive layer M2 may include a metal layer, an indium tin oxide layer, and the like. A capacitor dielectric layer may be disposed between the first conductive layer M1 and the second conductive layer M2. The first film layer group 220 may include one or both of the first conductive layer M1 and the second conductive layer M2. The display device may further include an active layer, and a gate insulating layer may be disposed between the active layer and the first conductive layer. The active layer may be configured to form a channel region, a source region and a drain region of the transistor in the at least one pixel circuit.

The first wire 221 may be located in one or both of the first conductive layer M1 and the second conductive layer M2. The at least one third wire 222 may be located in one or both of the first conductive layer M1 and the second conductive layer M2.

It is to be noted that FIG. 18 exemplarily shows a film layer relationship between the first partition 201 and the second partition 202 in a cross-sectional structure. It is to be understood by those skilled in the art the film layer relationship may also represent a film layer relationship between the first partition 201 and the third partition 203 in a cross-sectional structure, and represent a film layer relationship between the first partition 201 and the fourth partition 204 in a cross-sectional structure.

With continued reference to FIG. 18, optionally, two adjacent first wires 221 are located in different film layers, and first wires 221 on two sides among three adjacent first wires 221 are located in the same film layer. With this arrangement, it is conducive to maximizing utilization of the wiring space of the display device, thereby further increasing the number of wires, or further reducing the width of the bezel.

On the basis of the above-described embodiments, optionally, the thickness of the second wire 231 is greater than the thickness of the first wire 221. In some embodiments, the material of the first wire 221 includes molybdenum, and a thickness of the molybdenum ranges from 1000 angstroms to 4000 angstroms. The material of the second wire 231 includes titanium aluminum titanium. A thickness of a first layer of titanium ranges from 300 angstroms to 2000 angstroms, a thickness of an intermediate layer of titanium ranges from 3000 angstroms to 9000 angstroms, and a thickness of a second layer of titanium ranges from 300 angstroms to 2000 angstroms. A square resistance of the second wire 231 may be less than a square resistance of the first wire 221. The second wire 231 has a smaller impedance and is more suitable for transmitting a power type signal. It can be learned from the foregoing analysis that, in the embodiments of the present disclosure, the second wire 231 and the first wire 221 in the first partition 201 are disposed in a staggered manner, so that a height from a bottom surface of the second wire 231 to the substrate 210 is reduced. Therefore, even if the thickness of the second wire 231 is greater than the thickness of the first wire 221, in the embodiments of the present disclosure, a height from a top surface of the second wire 231 to the substrate 210 can still be reduced, thereby reducing a height from the sealing part 240 located on the second wire 231 to the substrate 210. The second film layer group 230 may include a third conductive layer M3. The third conductive layer M3 may include a metal layer, an indium tin oxide layer, and the like. The third conductive layer M3 may be further configured to form the source and/or the drain of the transistor in the. A thickness of the second film layer group 230 may be greater than the thickness of the first film layer group 220. A thickness of the third conductive layer M3 may be greater than a thickness of the first conductive layer M1. The thickness of the third conductive layer M3 may be greater than a thickness of the second conductive layer M2. The thickness of the third conductive layer M3 may be greater than or equal to a sum of the thicknesses of the first conductive layer M2 and the second conductive layer M2. The first insulating layer may be disposed between the second conductive layer M2 and the third conductive layer M3.

With continued reference to FIG. 11 to FIG. 18, on the basis of the above-described embodiments, optionally, the display device further includes a first insulating layer 250. The first insulating layer 250 is located between the first film layer group 220 and the second film layer group 230. At least in the first partition 201, the first insulating layer 250 is located between the first wire 221 and the sealing part 240, and the first insulating layer 250 is in contact with the sealing part 240.

Optionally, referring to FIG. 18, at least in the first partition 201 and in the overlapping region between the orthographic projection of the sealing part 240 on the substrate 210 and the orthographic projection of the first insulating layer 250 on the substrate 210, the sealing part 240 overlaps with at least part of the orthographic projection of the at least one second wire 231 on the substrate 210, which is equivalent to that the first insulating layer 250 below the at least one second wire 231 covered by the sealing part 240 is reserved, that is, a first opening is not provided. The setting manner of the first insulating layer 250 in the first partition 201 not only has the function of insulating the first film layer group 220 and the second film layer group 230, but also may be used for making the first insulating layer 250 be in contact with the sealing part 240, thereby enhancing the sealing performance of the sealing part 240 in the first partition 201.

With continued reference to FIG. 11 to FIG. 18, on the basis of the above-described embodiments, optionally, in the second partition 202 and/or the third partition 203, the overlapping region between the orthographic projection of the sealing part 240 on the substrate 210 and the orthographic projection of the first insulating layer 250 on the substrate 210 overlaps with part of the orthographic projection of the second wire 231 on the substrate 210, which is equivalent to that the first insulating layer 250 below the second wire 231 covered by the sealing part 240 is reserved, that is, the second opening is not provided. The setting manner of the first insulating layer 250 in the second partition 202 and/or the third partition 203 has the function of insulating the first film layer group 220 and the second film layer group 230.

FIG. 19 is another cross-sectional view taken along G-G of FIG. 10. In another embodiment of the present disclosure, optionally, at least in the first partition 201, the first insulating layer 250 includes a first opening, and in an overlapping region between the orthographic projection of the sealing part 240 on the substrate 210 and an orthographic projection of the first opening 251 on the substrate 210, the orthographic projection of the sealing part 240 on the substrate 210 overlaps with at least part of the orthographic projection of the second wire 231 on the substrate 210, which is equivalent to that the first insulating layer 250 below the second wire 231 covered by the sealing part 240 is removed or thinned, that is, the first opening is provided, for example, the first opening may be a groove or a through hole that runs through the first insulating layer 250. With this arrangement, a bottom surface of the second wire 231 is flush with a bottom surface of the first wire 221, so that a height of the top surface of the second wire 231 is further reduced, thereby reducing a height of the sealing part 240 located in the first partition 201, reducing a height difference of the sealing part 240 located in different partitions (such as, the first partition 201 and the second partition 202, the first partition 201 and the third partition 203), and improving the display effect of the display device. Alternatively, from another perspective, in the embodiments of the present disclosure, the thickness of the second wire 231 can be increased on the basis that the height of the sealing part 240 remains unchanged, thereby reducing the impedance of the second wire 231.

It is to be noted that FIG. 19 exemplarily shows a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

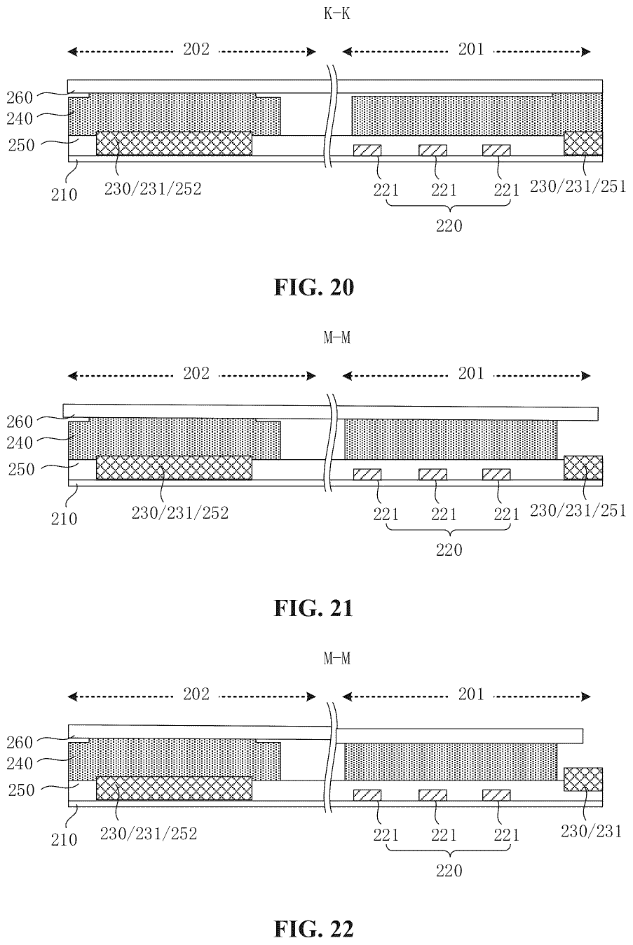

FIG. 20 is another cross-sectional view taken along K-K of FIG. 14, and FIG. 21 is another cross-sectional view taken along M-M of FIG. 16. In another embodiment of the present disclosure, optionally, in the second partition 202 and/or the third partition 203, the first insulating layer 250 includes a second opening 252, in the second partition 202 and/or the third partition 203, an overlapping region between the orthographic projection of the sealing part 240 on the substrate 210 and an orthographic projection of the second opening 252 on the substrate 210 overlaps with at least part of the orthographic projection of the at least one second wire 231 on the substrate 210, which is equivalent to that the first insulating layer 250 below the at least one second wire 231 covered by the sealing part 240 is removed or thinned, that is, the second opening is provided, for example, the second opening may be a groove or a through hole that runs through the first insulating layer 250. With this arrangement, a bottom surface of the second wire 231 is flush with a bottom surface of the first wire 221, so that a height of the top surface of the second wire 231 is further reduced, and a height of the sealing part 240 located in the second partition 202 and/or the third partition 203 is reduced. Alternatively, from another perspective, in the embodiments of the present disclosure, the thickness of the second wire 231 can be increased on the basis that the height of the sealing part 240 remains unchanged, thereby reducing the impedance of the second wire 231.

It can be seen that the first opening and/or the second opening in the first insulating layer 250 are mainly disposed to reduce the height of the film layer of the at least one second wire 231 and setting manners of the first opening and/or the second opening may be adjusted as required in practical application. For example, FIG. 22 is another cross-sectional view taken along M-M of FIG. 16. In another embodiment of the present disclosure, optionally, in the second partition 202 and/or the third partition 203, an overlapping region between the orthographic projection of the sealing part 240 on the substrate 210 and the orthographic projection of the second opening on the substrate 210 overlaps with at least part of the orthographic projection of the second wire 231 on the substrate 210. In the first partition 201, the first opening is not disposed in the first insulating layer 250. Optionally, in the first partition 201, the orthographic projection of the second wire 231 on the substrate 210 is located outside the orthographic projection of the sealing part 240 on the substrate 210.

Optionally, in the first partition 201, the second partition 202 and the third partition 203, a gate insulating layer GI and/or a capacitor dielectric layer CI may be disposed between the at least one second wire 231 and the substrate 210. Optionally, in the first partition 201, the first opening may extend to the capacitor dielectric layer CI, for example, the first opening may penetrate the capacitor dielectric layer. Optionally, in the second partition 202 and/or the third partition 203, the second opening may extend to the capacitor dielectric layer CI, for example, the second opening may penetrate the capacitor dielectric layer CI. Optionally, in the first partition 201, the first opening may extend to the gate insulating layer GI, for example, the first opening may penetrate the gate insulating layer GI. Optionally, in the second partition 202 and/or the third partition 203, the second opening may extend to the gate insulating layer GI, for example, the second opening may penetrate the gate insulating layer.

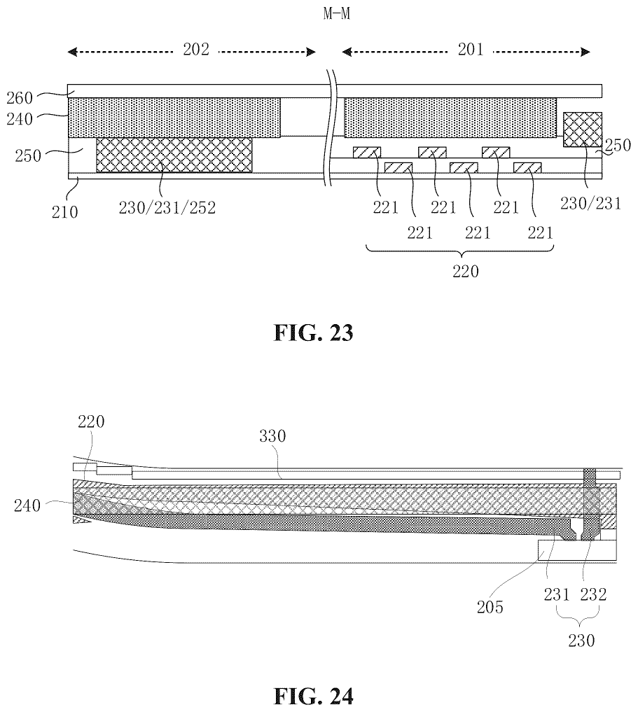

FIG. 23 is another cross-sectional view taken along M-M of FIG. 16. In another embodiment of the present disclosure, optionally, unlike the embodiment shown in FIG. 22, in the first partition 201, at least two first wires 221 are located in different film layers. Optionally, in the second partition 202 and/or the third partition 203, the sealing part 240 covers at least part of the at least one second wire 231. Optionally, in the second partition 202 and/or the third partition 203, the first insulating layer 250 below the one second wire 231 covered by the sealing part 240 is removed or thinned (as shown in FIG. 23) or retained. Optionally, in the first partition 201, the first insulating layer 250 below the one second wire 231 is retained (as shown in FIG. 23), or removed, or thinned. Optionally, in the first partition 201, the sealing part 240 may cover the second wire 231 or may not cover the second wire 231 (as shown in FIG. 23).

It is to be noted that FIG. 20 to FIG. 23 exemplarily show a film layer relationship between the first partition 201 and the second partition 202 in a cross-sectional structure. It is to be understood by those skilled in the art that the film layer relationship may also represent a film layer relationship between the first partition 201 and the third partition 203 in a cross-sectional structure, and represent a film layer relationship between the first partition 201 and the fourth partition 204 in a cross-sectional structure.

Optionally, the display device further includes a second insulating layer located on one side of the second film layer group 230 facing away from the substrate 210. In the second partition 202 and/or the third partition 203, the second insulating layer is located between the sealing part 240 and the at least one second wire 231. The second insulating layer may be an inorganic insulating layer. In the second partition 202 and/or the third partition 203, the overlapping region between the orthographic projection of the at least one second wire 231 on the substrate 210 and the orthographic projection of the sealing part 240 on the substrate 210 overlaps with at least part of the orthographic projection of the second insulating layer on the substrate 210. The sealing part 240 is in contact with the second insulating layer, which is conducive to improving the encapsulation effect.

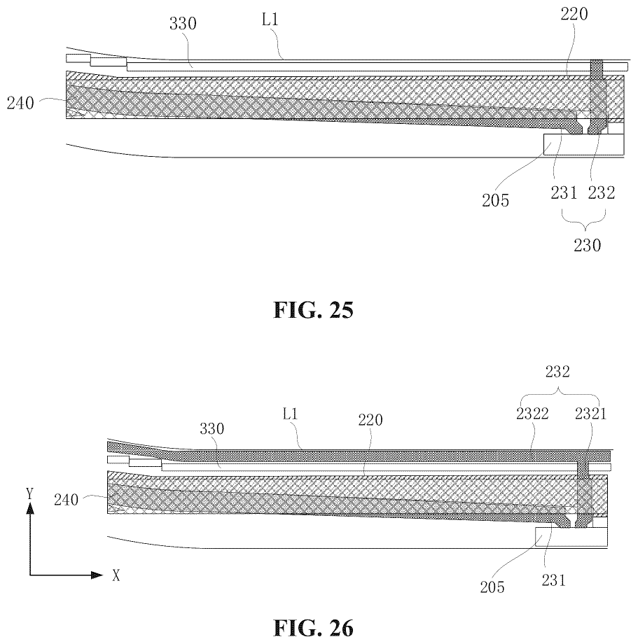

FIG. 24 is a partial top view of a first partition of another display device according to an embodiment of the present disclosure, and FIG. 25 is a partial top view of a first partition of another display device according to an embodiment of the present disclosure. Referring to FIG. 24 and FIG. 25, on the basis of the above-described embodiments, optionally, the sealing part 240 is located on one side of the second film layer group 230 facing away from the substrate 210. The second film layer group 230 further includes at least one fourth wire 232, and the at least one fourth wire 232 is at least located in the first partition 201. Optionally, the at least one fourth wire 232 includes at least one first wire segment 2321 that extends in a first direction Y. The first direction Y is perpendicular to an edge L1 of the display region AA facing the first partition 201. Optionally, in the first partition 201, an overlapping region between an orthographic projection of the at least one fourth wire 232 on the substrate 210 and the orthographic projection of the sealing part 240 on the substrate 210 is perpendicular to the edge L1 of the display region AA facing the first partition 201. An extension direction of the fourth wire 232 is perpendicular to the edge L1, which is conducive to reducing the size of the fourth wire 232 located below the sealing part 240, thereby reducing the impact of the fourth wire 232 on the height of the sealing part 240. A thickness of the fourth wire 232 may be greater than the thickness of the first wire 221.

With continued reference to FIG. 24 and FIG. 25, optionally, the at least one fourth wire 232 and the at least one second wire 231 are located in the same film layer. The at least one second wire 231 and the first film layer group 220 are disposed in different layers; therefore, the at least one fourth wire 232 and the first film layer group 220 are disposed in different layers, which is beneficial for the at least one fourth wire 232 to cross over from the first film layer group 220.

FIG. 26 is a partial top view of a first partition of another display device according to an embodiment of the present disclosure. Referring to FIG. 26, on the basis of above-described embodiments, optionally, the at least one fourth wire 232 includes at least one first wire segment 2321 that extends in the first direction Y and at least one second wire segment 2322 that extends in a second direction X. The sealing part 240 located in the first partition 201 covers at least part of the at least one first wire segment 2321, that is, at least part of an orthographic projection of the at least one first wire segment 2321 on the substrate overlaps with the orthographic projection of the sealing part 240 on the substrate. An orthographic projection of the at least one second wire segment 2322 on the substrate 210 is located outside the orthographic projection of the sealing part 240 on the substrate 210 and is located on one side of the sealing part 240 facing the display region AA, the first direction Y intersects the second direction X, and the first direction Y is perpendicular to the edge L1 of the display region AA facing the first partition 201. The orthographic projection of the second wire segment 2322 on the substrate 210 may not overlap with the orthographic projection of the sealing part 240 on the substrate 210. The at least one second wire segment 2322 and the sealing part 240 may be disposed in a staggered manner. With this arrangement, on one hand, the at least one second wire segment 2322 is disposed so that the uniformity of the signal of the at least one fourth wire 232 can be increased; on the other hand, the sealing part 240 is avoided by the at least one second wire segment 2322, which is conducive to reducing the size of the at least one fourth wire 232 located below the sealing part 240, thereby reducing the impact of the at least one fourth wire 232 on the height of the sealing part 240. Optionally, the second direction is parallel to the edge of the display region facing the first partition.

In the above-described embodiments, a condition that in the first partition 201, the orthographic projection of the second film layer group 230 on the substrate is located outside an overlapping region between the orthographic projection of the first film layer group 220 on the substrate and the orthographic projection of the sealing part 240 on the substrate is shown exemplarily, which is not a limitation on the present disclosure. In other embodiments, in the first partition 201 and in a region covered by the sealing part 240, part of the wire in the second film layer group 230 is set to overlap with part of the wire in the first film layer group 220, but an overlapping area needs to be limited, which will be specifically described below.

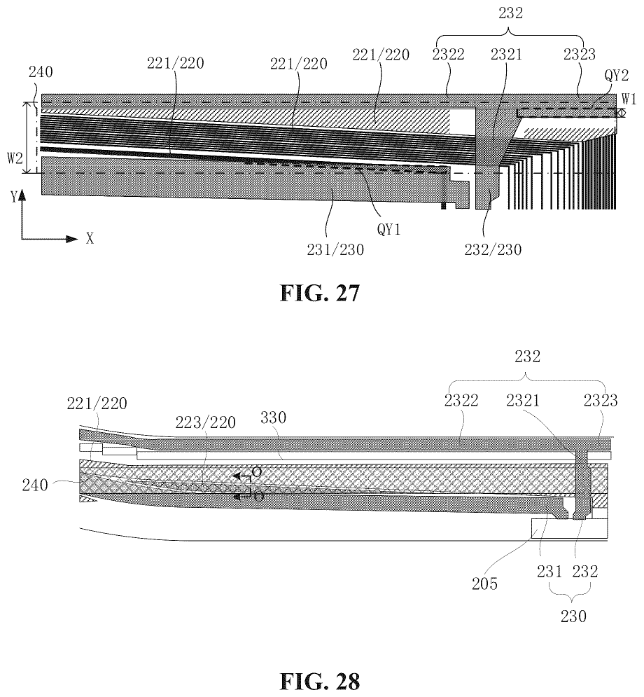

FIG. 27 is a partial top view of a first partition of another display device according to an embodiment of the present disclosure. Referring to FIG. 27, the sealing part 240 is represented by a dotted box. On the basis of the above-described embodiments, optionally, the at least one fourth wire 232 further includes at least one third wire segment 2323 that extends in the second direction X, a region where the orthographic projection of the first film layer group 220 on the substrate, the orthographic projection of the sealing part 240 on the substrate, an orthographic projection of the at least one third wire segment 2323 on the substrate, and the first partition overlap simultaneously is a second region QY2, and in the first direction Y, a width W1 of the second region QY2 is less than or equal to 15% of a width W2 of an overlapping region between the orthographic projection of the sealing part 240 on the substrate and the first partition. The second region QY2 is a region in which the stacked number of film layers of a wire layer in the first partition is relatively large. In the embodiments of the present disclosure, a proportion of the area of the second region QY2 in the first partition is set to be less than 15%, which is conducive to improving the phenomenon of Newton's rings and thus improving the display quality. Optionally, in the first direction Y, the width W1 of the second region QY2 is less than or equal to 10% of the width W2 of the overlapping region between the orthographic projection of the sealing part 240 on the substrate and the first partition. Optionally, in the first direction Y, the width W1 of the second region QY2 is less than or equal to 5% of the width W2 of the overlapping region between the orthographic projection of the sealing part 240 on the substrate and the first partition.

With continued reference to FIG. 27, in another embodiment, optionally, a region where the orthographic projection of the first film layer group 220 on the substrate, the orthographic projection of the sealing part 240 on the substrate, the orthographic projection of the at least one second wire 231 on the substrate, and the first partition overlap simultaneously is a first region QY1, and an area of the first region QY1 is less than 15% an area of the overlapping region between the orthographic projection of the sealing part 240 on the substrate and the first partition. Compared with regions in the first partition other than the first region QY1 and the second region QY2, the first region QY1 is a region in which the stacked number of film layers of a wire layer in the first partition is relatively large. In the embodiments of the present disclosure, a proportion of the area of the first region QY1 in the first partition is set to be less than 15%, which is conducive to improving the phenomenon of Newton's rings and thus improving the display quality. Optionally, the area of the first region QY1 is less than 10% of the area of the overlapping region between the orthographic projection of the sealing part 240 on the substrate and the first partition. Optionally, an area of the first region QY1 is less than 5% of the area of the overlapping region between the orthographic projection of the sealing part 240 on the substrate and the first partition.

With continued reference to FIG. 27, in another embodiment, optionally, the number of first wires 221 whose orthographic projections on the substrate at least partially overlap with the first region QY1 is less than or equal to 4. The first wires 221 are symmetrically distributed in the first partition. FIG. 27 shows a wiring structure on one side of a symmetric axis. FIG. 27 exemplarily shows on one side of the symmetry axis, the number of first wires 221 whose orthographic projections on the substrate at least partially overlap with the first region QY1 is 1, in this case, on two sides of the symmetry axis, the number of first wires 221 whose orthographic projections on the substrate at least partially overlap with the first region QY1 is 2. In other embodiments, on one side of the symmetry axis, the number of first wires 221 whose orthographic projections on the substrate at least partially overlap with the first region QY1 is set to be 2. Optionally, the number of first wires 221 whose orthographic projections on the substrate at least partially overlap with the first region QY1 is less than or equal to 2. In the first partition, an extension direction of one or more first wires 221 near the second wire 231 may be the same as an extension direction of the second wire 231. The first partition may include two sub-region arranged in the second direction Y, and in each sub-region, the number of first wires 221 whose orthographic projections on the substrate at least partially overlap with the first region QY1 is less than or equal to 2, such as 1. The first wires of the two sub-regions may be symmetrically disposed and/or the second wires of the two sub-regions may be symmetrically disposed. Optionally, the second wire 231 is a first power line ELVSS, and the fourth wire 232 is a second power line ELVDD. For example, one of the first power line ELVSS and the second power line ELVDD is a high voltage power line, and the other of the first power line ELVSS and the second power line ELVDD is a low voltage power line. The first power line ELVSS may be the low voltage power line. The second power line ELVDD may be the high voltage power line.

FIG. 28 is a partial top view of a first partition of another display device according to an embodiment of the present disclosure. Referring to FIG. 28, in another embodiment of the present disclosure, optionally, the orthographic projection of the third wire segment 2323 on the substrate is located outside the orthographic projection of the sealing part 240 on the substrate, and the third wire segment 2323 is located on the side of the sealing part 240 facing the display region. Compared with the foregoing embodiments, the third wire segment 2323 is disposed so that the stacked number of film layers of the wire layer below the sealing part 240 cannot be increased, thereby facilitating improvement of the phenomenon of Newton's rings.

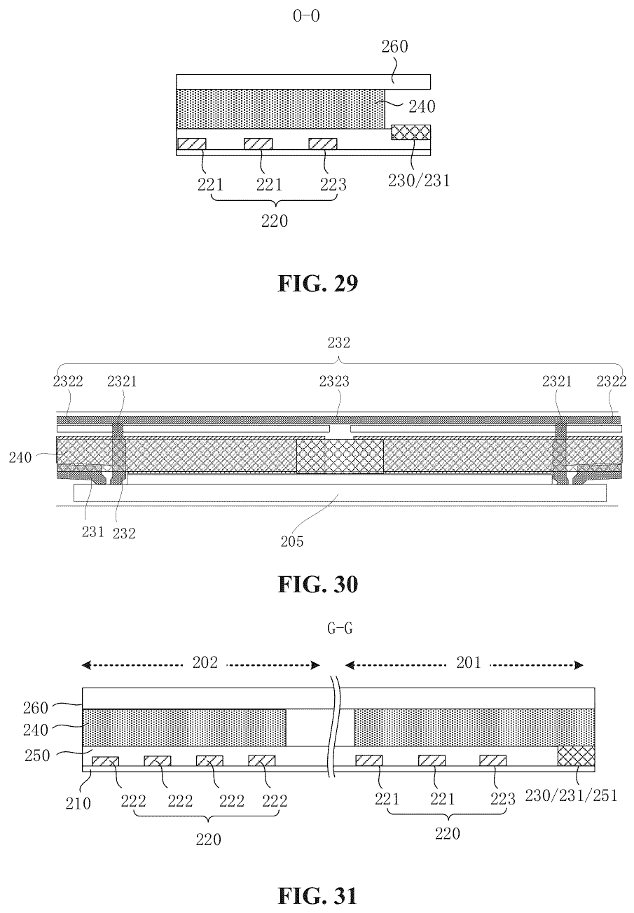

FIG. 29 is a cross-sectional view taken along 0-0 of FIG. 28. Referring to FIG. 28 and FIG. 29, on the basis of the above-described embodiments, optionally, the first film layer group 220 further includes a fifth wire 223. In the first partition 201, the fifth wire 223 is located between the first wires 221 and the second wire 231, and the sealing part 240 covers at least part of the fifth wire 223. Optionally, the fifth wire 223 is disposed in a floating manner, that is, the fifth wire 223 is not connected to the electric signal. The fifth wire 223 is disposed so that the heights of the film layers below the sealing part 240 are relatively uniform, the flatness is improved, and the encapsulation effect of the sealing part 240 is further improved. The fifth wire 223 and the first wire 221 are located in the same film layer, such as, the same film layer.

FIG. 30 is a partial top view of a first partition of another display device according to an embodiment of the present disclosure. Referring to FIG. 30, on the basis of above-described embodiments, optionally, two first wire segments 2321 are provided, two second wire segments 2322 are provided, and the third wire segment 2323 is located between the two second wire segments 2322. One end of the third wire segment 2323 is electrically connected to one first wire segment 2321 and one second wire segment 2322, and the other end of the third wire segment 2323 is electrically connected to the other first wire segment 2321 and the other second wire segment 2322.

With continued reference to FIG. 24 to FIG. 28, and FIG. 30, on the basis of the above-described embodiments, optionally, the display device further includes a bonding region 205, the bonding region 205 is located in the first partition 201 and located on one side of the orthographic projection of the sealing part 240 on the substrate 210 facing away from the display region AA. The bonding region 205 is used for bonding a flexible circuit board and/or a drive chip.

On the basis of the above-described embodiments, optionally, at least in the display region AA, the second film layer group 230 is located on one side of the first film layer group 220 facing away from the substrate 210.

FIG. 31 is another cross-sectional view taken along G-G of FIG. 10. Referring to FIG. 31, on the basis of the above-described embodiments, optionally, the display device further includes a cover plate 260, and the cover plate 260 is located on one side of the sealing part 240 facing away from the substrate 210. The sealing part 240 is used for bonding the array substrate and the cover plate 260. The array substrate may include a substrate 210, and a drive circuit layer and a light-emitting device layer that are located on the substrate 210. The drive circuit layer may be configured to form the at least one pixel circuit and the at least one scanning circuit. The light-emitting device layer may be configured to form at least one light-emitting element. Optionally, the sealing part 240 includes glass frit.

Optionally, at least part of the first wire 221 includes at least one of a start signal line, a clock signal line, a high potential direct current signal line, a low potential direct current signal line, or a signal connection line for transmitting a data signal.

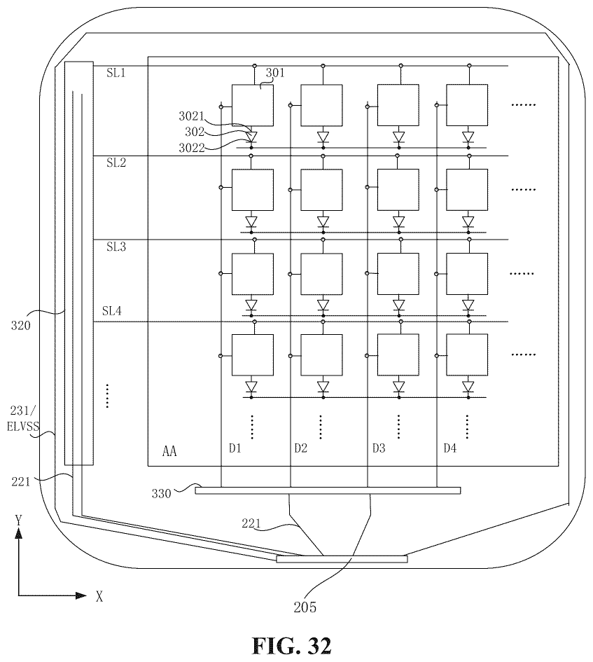

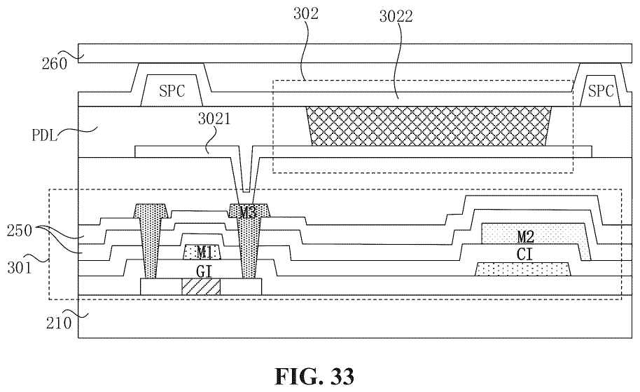

FIG. 32 is a structural diagram of another display device according to an embodiment of the present disclosure, and FIG. 33 is a cross-sectional view of a display region of a display device according to an embodiment of the present disclosure. Referring to FIG. 32 and FIG. 33, on the basis of the above-described embodiments, optionally, the display device further includes at least one pixel circuit 301 and at least one light-emitting element 302. The at least one pixel circuit 301 and the at least one light-emitting element 302 are located in the display region AA of the substrate 210, the at least one pixel circuit 301 is electrically connected to at least one first electrode 3021 of the at least one light-emitting element 302, and the at least one second wire 231 is electrically connected to at least one second electrode 3022 of the at least one light-emitting element 302. In some embodiments, the first electrode 3021 of the light-emitting element 302 is an anode, the second electrode 3022 of the light-emitting element 302 is a cathode, and the second wire 231 provides a common power voltage ELVSS to the light-emitting element 302. The second wire 231 is electrically connected to the second electrode 3022 of the light-emitting element 302.

With continued reference to FIG. 32, on the basis of the above-described embodiments, optionally, the display device further includes multiple data lines (for example, includes a data line D1, a data line D2, a data line D3, and a data line D4). The multiple data lines may be arranged in the second direction. The multiple data lines are located in the display region AA of the substrate 210. At least part of the first wires 221 are electrically connected to respective ones of the multiple data lines and include a signal connection line for transmitting a data signal, the data lines extend in the first direction Y, and the first partitions 201 and the display region AA are arranged in the first direction Y. In the first wires of the fan-out region 2011, the first wires 221 of the intermediate region extends in the first direction, and an extension direction of the first wires 221 on the two side regions is gradually inclined in the second direction (or gradually inclined in the extension direction of the at least one second wire 231). In the first partition 201, the extension direction of the at least one second wire 231 intersects the first direction.

With continued reference to FIG. 32, on the basis of the above-described embodiments, optionally, the signal connection line is connected between the data lines and the drive chip and is configured to transmit the output signal of the drive chip to the data lines. Optionally, a multiplexing circuit 330 is also disposed between the signal connection line and the data lines, and the multiplexing circuit 330 is configured to transmit the data signal on the signal connection line to at least two data lines in a time-division manner, to reduce the number of pins of the drive chip.

With continued reference to FIG. 32, on the basis of the above-described embodiments, optionally, the display device further includes at least one scanning circuit 320. The at least one scanning circuit 320 is located in the bezel region (for example, the at least one scanning circuit is located in the second partition 202) of the substrate 210. At least part of the first wire 221 is electrically connected to the scanning circuit and includes at least one of a start signal line, a clock signal line, a high potential direct current signal line, or a low potential direct current signal line. The scanning circuit 320 is configured to provide a scanning signal and/or a light emission control signal to the display region AA through the scanning line (such as, a scanning line SL1, a scanning line SL2, a scanning line SL3, and a scanning line SL4).

On the basis of the above-described embodiments, optionally, the display device is symmetrical about the second direction X, that is, a symmetric axis of display device extends in the first direction Y, and a wiring manner in the second partition 202 is the same as a wiring manner in the fourth partition 204. A cross-sectional structure of the third partition 203 and a cross-sectional structure of the fourth partition 204 are the same as or similar to a cross-sectional structure of the second partition 202, and the details are not repeated here.

The display device may include a mobile phone, a wearable device, a tablet computer, a notebook computer, and the like.

It is to be understood that various forms of flows, reordering, adding or deleting steps described above may be used. For example, the steps described in the present disclosure may be executed in parallel, sequentially, or in different orders, and are not limited herein as long as the desired results of the technical solutions of the present disclosure can be achieved.

The above implementations should not be construed as limiting the scope of protection of the present disclosure. It is to be understood by those skilled in the art that various modifications, combinations, sub-combinations and substitutions may be made according to the design requirements and other factors. Any modification, equivalent replacement, and improvement made within the spirit and principle of the present disclosure should be included within the scope of protection of the present disclosure.

What is claimed is:

1. A display device, comprising:
a substrate, wherein the substrate comprises a display region and a bezel region, the bezel region comprises a first partition, and the first partition comprises at least part of a fan-out region;
a first film layer group located on the substrate, wherein the first film layer group comprises a plurality of first wires, and the plurality of first wires are located at least in the fan-out region;
a second film layer group located on the substrate, wherein the second film layer group comprises at least one second wire; and
a sealing part located in the bezel region and on one side of the first film layer group facing away from the substrate, wherein at least in the first partition, an orthographic projection of the at least one second wire on the substrate is located outside an overlapping region between an orthographic projection of the first film layer group on the substrate and an orthographic projection of the sealing part on the substrate, or a region where an orthographic projection of the first film layer group on the substrate, an orthographic projection of the sealing part on the substrate, an orthographic projection of the at least one second wire on the substrate, and the first partition overlap is a first region, and an area of the first region is less than 15% an area of an overlapping region between the orthographic projection of the sealing part on the substrate and the first partition, or the number of first wires whose orthographic projections on the substrate at least partially overlap with the first region is less than or equal to 4.

2. The display device of claim 1, wherein the sealing part is located on one side of the second film layer group facing away from the substrate, and the sealing part covers at least part of the at least one second wire at least in the first partition.

3. The display device of claim 1, wherein an overlapping region between the orthographic projection of the at least one second wire on the substrate and the first partition is located outside the overlapping region between the orthographic projection of the sealing part on the substrate and the first partition.

4. The display device of claim 1, wherein at least in the first partition, the at least one second wire is located on one side of the plurality of first wires facing away from the display region.

5. The display device of claim 1, wherein the bezel region further comprises a second partition and a third partition, the second partition and the first partition are separately located on two adjacent sides of the display region, the first partition and the third partition are separately located on two opposite sides of the display region; and
in the second partition and the third partition, an orthographic projection of one of the first film layer group and the second film layer group on the substrate overlaps with the orthographic projection of the sealing part on the substrate, and an orthographic projection of the other of the first film layer group and the second film layer group on the substrate is located outside the orthographic projection of the sealing part on the substrate.

6. The display device of claim 1, wherein the bezel region further comprises a second partition and a third partition, the second partition and the first partition are separately located on two adjacent sides of the display region, the first partition and the third partition are separately located on two opposite sides of the display region;
the first film layer group further comprises at least one third wire located in at least one of the second partition and the third partition; in at least one of the second partition and the third partition, the sealing part covers at least part of the at least one third wire.

7. The display device of claim 6, wherein the at least one second wire and at least one first wire among the plurality of first wires extend from the first partition to the second partition; in the second partition, the at least one third wire is located on one side of the at least one second wire facing away from the plurality of first wires.

8. The display device of claim 6, wherein the at least one second wire extends from the first partition to the third partition via the second partition, and the at least one third wire extends from the second partition to the third partition; in the third partition, the at least one third wire is located on one side of the at least one second wire facing away from the display region;
the at least one third wire is electrically connected to the at least one second wire;
the at least one third wire and the plurality of first wires are located on a same film layer; and
the display device further comprises a first insulating layer located between the first film layer group and the second film layer group; in at least one of the second partition and the third partition, the first insulating layer is located between the at least one third wire and the sealing part, and the first insulating layer is in contact with the sealing part.

9. The display device of claim 1, wherein the bezel region further comprises a second partition and a third partition, the second partition and the first partition are separately located on two adjacent sides of the display region, the first partition and the third partition are separately located on two opposite sides of the display region;
the at least one second wire extends from the first partition to the second partition, the at least one second wire extends from the first partition to the third partition via the second partition;
in at least one of the second partition and the third partition, the sealing part covers at least part of the at least one second wire;
at least one first wire among the plurality of first wires extends from the first partition to the second partition; and
the at least one first wire extending to the second partition comprises at least one of: a start signal line, a clock signal line, a high potential direct current signal line, or a low potential direct current signal line.

10. The display device of claim 1, wherein at least two first wires among the plurality of first wires are located in different film layers, and two adjacent first wires among the plurality of first wires are located in different film layers, and first wires on two sides among three adjacent first wires are located on a same film layer.

11. The display device of claim 1, wherein a thickness of the at least one second wire is greater than a thickness of a first wire of the plurality of first wires.

12. The display device of claim 1, wherein the display device further comprises a first insulating layer located between the first film layer group and the second film layer group; and
at least in the first partition, the first insulating layer is located between the plurality of first wires and the sealing part, and the first insulating layer is in contact with the sealing part.

13. The display device of claim 12, wherein,
at least in the first partition, an overlapping region between the orthographic projection of the sealing part on the substrate and an orthographic projection of the first insulating layer on the substrate overlaps with at least part of the orthographic projection of the at least one second wire on the substrate; or
at least in the first partition, the first insulating layer comprises a first opening, and an overlapping region between the orthographic projection of the sealing part on the substrate and an orthographic projection of the first opening on the substrate overlaps with at least part of the orthographic projection of the at least one second wire on the substrate;
the bezel region further comprises a second partition and a third partition, the second partition and the first partition are separately located on two adjacent sides of the display region, the first partition and the third partition are separately located on two opposite sides of the display region; in at least one of the second partition and the third partition, an overlapping region between the orthographic projection of the sealing part on the substrate and the orthographic projection of the first insulating layer on the substrate overlaps with at least part of the orthographic projection of the at least one second wire on the substrate; or
in at least one of the second partition and the third partition, the first insulating layer comprises a second opening; in at least one of the second partition and the third partition, an overlapping region between the orthographic projection of the sealing part on the substrate and an orthographic projection of the second opening on the substrate overlaps with at least part of the orthographic projection of the at least one second wire on the substrate.

14. The display device of claim 1, wherein the sealing part is located on one side of the second film layer group facing away from the substrate, the second film layer group further comprises at least one fourth wire located at least in the first partition, and the at least one fourth wire comprises at least one first wire segment extending in a first direction; and
in the first partition, at least part of an orthographic projection of the at least one first wire segment on the substrate overlaps with the orthographic projection of the sealing part on the substrate, and the first direction is perpendicular to an edge of the display region facing the first partition.

15. The display device of claim 14, wherein the at least one fourth wire and the at least one second wire are located on a same film layer;
the at least one fourth wire further comprises at least one second wire segment extending in a second direction and located in the first partition, the sealing part covers at least part of the at least one first wire segment, an orthographic projection of the at least one second wire segment on the substrate is located outside the orthographic projection of the sealing part on the substrate and is located on one side of the sealing part facing the display region, and the first direction intersects the second direction;
the second direction is parallel to an edge of the display region facing the first partition; and
the at least one second wire is a first power line, and the at least one fourth wire is a second power line.

16. The display device of claim 15, wherein the display device further comprises at least one pixel circuit and at least one light-emitting element which are located in the display region of the substrate, the at least one pixel circuit is electrically connected to at least one first electrode of the at least one light-emitting element, the at least one second wire is electrically connected to at least one second electrode of the at least one light-emitting element, and the at least one fourth wire is electrically connected to the at least one pixel circuit; and
the at least one fourth wire further comprises a third wire segment extending in the second direction, a region where the orthographic projection of the first film layer group on the substrate, the orthographic projection of the sealing part on the substrate, an orthographic projection of the third wire segment on the substrate, and the first partition overlap is a second region, and in the first direction, a width of the second region is less than or equal to 15% of a width of the overlapping region between the orthographic projection of the sealing part on the substrate and the first partition; or an orthographic projection of the third wire segment on the substrate is located outside the orthographic projection of the sealing part on the substrate, and the third wire segment is located on one side of the sealing part facing the display region.

17. The display device of claim 16, wherein two first wire segments are provided, two second wire segment are provided, the third wire segment is located between the two second wire segments, one end of the third wire segment is electrically connected to one first wire segment of the two first wire segments and one second wire segment of the two second wire segments, and the other end of the third wire segment is electrically connected to the other first wire segment of the two first wire segments and the other second wire segment of the two second wire segments.

18. The display device of claim 1, wherein the plurality of first wires comprises at least one of: a start signal line, a clock signal line, a high potential direct current signal line, a low potential direct current signal line, or a signal connection line for transmitting a data signal;
the display device further comprises at least one pixel circuit and at least one light-emitting element which are located in the display region of the substrate, the at least one pixel circuit is electrically connected to at least one first electrode of the at least one light-emitting element, and the at least one second wire is electrically connected to at least one second electrode of the at least one light-emitting element; and
the display device further comprises a plurality of data lines located in the display region of the substrate, at least part of the plurality of first wires are electrically connected to respective ones of the plurality of data lines and comprise a signal connection line for transmitting a data signal, the plurality of data lines extend in a first direction, and the first partition and the display region are arranged in the first direction.

19. The display device of claim 1, the display device further comprises at least one scanning circuit located in the bezel region of the substrate, at least part of the plurality of first wires are electrically connected to the at least one scanning circuit and comprise at least one of a start signal line, a clock signal line, a high potential direct current signal line, or a low potential direct current signal line;
at least in the display region, the second film layer group is located on one side of the first film layer group facing away from the substrate;
the display device further comprises a cover plate, and the cover plate is located on one side of the sealing part facing away from the substrate;
the display device further comprises a bonding region, the bonding region is located in the first partition and located on one side of the orthographic projection of the sealing part on the substrate facing away from the display region; and
the sealing part comprises glass powder.

20. The display device of claim 2, wherein the first film layer group further comprises a fifth wire located in the first partition and located between the plurality of first wires and the at least one second wire, and the sealing part covers at least part of the fifth wire; and
the fifth wire is disposed in a floating manner.
